(19) United States
(12) Patent Application Publication
(10) Pub. No.: US 2026/0128192 A1
(43) Pub. Date: May 7, 2026

(54) CABLE DESIGN FOR ALL-ELECTRIC AIRCRAFT

(71) Applicant: Board of Regents, The University of Texas System, Austin, TX (US)

(72) Inventors: Mona Ghassemi, Allen, TX (US); Arian Azizi, Richardson, TX (US); Anoy Saha, Dallas, TX (US)

(21) Appl. No.: 18/932,270

(22) Filed: Oct. 30, 2024

Related U.S. Application Data
(60) Provisional application No. 63/594,338, filed on Oct. 30, 2023.
(60) Provisional application No. 63/594,351, filed on Oct. 30, 2023.

(51) Int. Cl. H01B 7/02; G06F 30/23; H01B 7/29

(52) U.S. Cl. CPC H01B 7/0216; G06F 30/23; H01B 7/29

(57) ABSTRACT

A cable for use in high power delivery and low system mass electric power systems (EPSs) in electrified aircraft is disclosed. In one embodiment, the cable comprises at least one conductor, at least one insulator, and a jacket.

### CROSS-REFERENCE TO RELATED APPLICATION

This application claims the benefit of U.S. Provisional Application Ser. No. 63/594,338 filed Oct. 30, 2023, by Mona Ghassemi and Arian Azizi, entitled “DESIGN OF A CABLE SYSTEM FOR A HIGH-POWER MVDC AIRCRAFT ELECTRIC POWER SYSTEM” and U.S. Provisional Application Ser. No. 63/594,351 filed Oct. 30, 2023, by Mona Ghassemi, Arian Aziz, and Anoy Saha, entitled “HIGH POWER DENSITY MEDIUM VOLTAGE DIRECT CURRENT CABLES FOR ALL-ELECTRIC AIRCRAFT”, commonly assigned with this application and incorporated herein by reference in their entirety.

### STATEMENT OF GOVERNMENT INTEREST

This invention was made with government support under contract number DE-AR0001677 awarded by the Advanced Research Projects Agency-Energy (ARPA-E). The government has certain rights in the invention.

### TECHNICAL FIELD

This application is directed, in general, to designing cables for high power delivery and low system mass electric power systems (EPSs) in electrified aircraft.

### BACKGROUND

Aircraft electrification yields the next generation of aircraft such as more electric aircraft (MEA) and all electric aircraft (AEA). These aircraft require high power-density and low system-mass electric power systems (EPS). To this end, the voltage of the system must be enhanced to reach medium voltage levels in a few kV ranges. However, using medium voltage (MV) EPS for aircraft exacerbates the challenges of designing aircraft cables such as arc and arc tracking, partial discharges (PD), and thermal management.

### BRIEF DESCRIPTION OF THE DRAWINGS

Reference is now made to the following descriptions taken in conjunction with the accompanying drawings, in which:

FIG. 1 is an illustration of a 2D finite element method (FEM) model of an EPS cable according to one or more embodiments of the disclosure;

FIG. 2 is an illustration of an equivalent thermal circuit of the cable in the steady-state according to one or more embodiments of the disclosure;

FIG. 3 is an illustration of a multi-layer insulation system according to one or more embodiments of the disclosure;

FIG. 4 is an illustration of a geometry of a cable according to one or more embodiments of the disclosure;

FIG. 5a is an illustration of a multi-layer, multi-function electrical insulation (MMEI) structure for the insulation part of an SC-M22759/87-04 cable according to one or more embodiments of the disclosure;

FIG. 5b is an illustration of an MMEI structure for the insulation part of a T-MMEI cable according to one or more embodiments of the disclosure;

FIG. 5c is an illustration of an MMEI structure for the insulation part of an SC-T-MMEI cable according to one or more embodiments of the disclosure;

FIG. 5d is an illustration of an MMEI structure for the insulation part of an ARC-SC-T-MMEI cable according to one or more embodiments of the disclosure;

FIG. 5e is an illustration of an MMEI structure for the insulation part of an PD-T-MMEI cable according to one or more embodiments of the disclosure;

FIG. 5f is an illustration of an MMEI structure for the insulation part of an ARC-PD-T-MMEI cable according to one or more embodiments of the disclosure;

FIG. 5g is an illustration of an MMEI structure for the insulation part of an IC-60502 cable according to one or more embodiments of the disclosure;

FIG. 5h is an illustration of an MMEI structure for the insulation part of an Tefzel cable according to one or more embodiments of the disclosure;

FIG. 5i is an illustration of an MMEI structure for the insulation part of an M22759/87-04 cable according to one or more embodiments of the disclosure;

FIG. 5j is an illustration of an MMEI structure for the insulation part of an MMEI cable according to one or more embodiments of the disclosure;

FIG. 6 is an illustration of a parts of the insulation systems that are placed between two potentials for screened and unscreened cables according to one or more embodiments of the disclosure;

FIGS. 7-11 illustrate the electric field norm and the electrical conductivity across the insulation of the designed cables according to one or more embodiments of the disclosure;

FIG. 12 is an illustration of a horizontal arrangement of the geometry of the cable according to one or more embodiments of the disclosure;

FIG. 13 is an illustration of a vertical arrangement of the geometry of the cable according to one or more embodiments of the disclosure;

FIG. 14 is an illustration of an equivalent thermal circuit of the cable in the steady-state according to one or more embodiments of the disclosure;

FIG. 15 is an illustration of a flow chart how the ampacity of the bipolar cable system is calculated according to one or more embodiments of the disclosure;

FIG. 16 is an illustration of a graph of an example of radiative heat compared to distance between poles of a horizontal arrangement of a cable according to one or more embodiments of the disclosure;

FIG. 17 is an illustration of a graph of an example of radiative heat compared to distance between poles of a vertical arrangement of a cable according to one or more embodiments of the disclosure;

FIG. 18 is an illustration of a graph of an example of convective heat compared to distance between poles of a horizontal arrangement of a cable according to one or more embodiments of the disclosure;

FIG. 19 is an illustration of a graph of an example of convective heat compared to distance between poles of a vertical arrangement of a cable according to one or more embodiments of the disclosure;

FIG. 20 is an illustration of a velocity field for a bipolar cable system experiences a velocity field in a horizontal configuration for a high air velocity according to one or more embodiments of the disclosure;

FIG. 21 is an illustration of a velocity field for a bipolar cable system experiences a velocity field in a vertical configuration for a high air velocity according to one or more embodiments of the disclosure;

FIG. 22 is an illustration of a velocity field for a bipolar cable system experiences a velocity field for a low air velocity according to one or more embodiments of the disclosure;

FIG. 23 is an illustration of a graph of an example of a comparison between the calculated ampacity of the bipolar cable system using the FEM and analytical model for a horizontal configuration according to one or more embodiments of the disclosure;

FIG. 24 is an illustration of a comparison between the calculated ampacity of the bipolar cable system using the FEM and analytical model for a vertical configuration according to one or more embodiments of the disclosure;

FIG. 25 is an illustration of a configuration of one of the poles where the ARC-SC-T-MMEI design was used in the cylindrical bipolar cable system according to one or more embodiments of the disclosure;

FIG. 26 is an illustration of a 2D geometry of a conventional cylindrical bipolar cable system according to one or more embodiments of the disclosure;

FIG. 27 is an illustration of a 2D geometry of a cuboid (square) bipolar cable system according to one or more embodiments of the disclosure;

FIG. 28 is an illustration of a 2D geometry of a coaxial bipolar cable system without a hollow inner conductor and the coaxial bipolar cable system with a hollow inner conductor according to one or more embodiments of the disclosure;

FIGS. 29-30 are illustrations of a graph of an example of a comparison of the weight per unit length and cross-sectional area of the cylindrical bipolar cable system, cuboid bipolar cable system, and coaxial bipolar cable system without a hollow inner conductor according to one or more embodiments of the disclosure;

FIG. 31 is an illustration of a graph of an example of J for three types of bipolar cable systems according to one or more embodiments of the disclosure;

FIG. 32 is an illustration of a graph of an example of radiative heat flux of the cylindrical bipolar cable system, cuboid bipolar cable system, and coaxial bipolar cable system without a hollow inner conductor according to one or more embodiments of the disclosure;

FIG. 33 is an illustration of a graph of an example of convective heat flux of the cylindrical bipolar cable system, cuboid bipolar cable system, and coaxial bipolar cable system without a hollow inner conductor according to one or more embodiments of the disclosure;

FIG. 34 is an illustration of a graph of an example of an electric field norm across the insulation of the bipolar cable systems according to one or more embodiments of the disclosure;

FIG. 35 is an illustration of a graph of an example of the weight per unit length and cross-section area compared to a diameter of the hollow area according to one or more embodiments of the disclosure;

FIG. 36 is an illustration of a graph of an example of radiative and convective heat fluxes of the designed cable with different diameters of the hollow area according to one or more embodiments of the disclosure;

FIG. 37 is a flowchart of a modeling procedure according to one or more embodiments of the disclosure;

FIG. 38 is an illustration of a configuration of a multilayer insulation system considered for cables according to one or more embodiments of the disclosure;

FIG. 39 is an illustration of a configuration of a multilayer insulation system considered for a cylindrical bipolar cable configuration of cables according to one or more embodiments of the disclosure;

FIG. 40 is an illustration of a configuration of a multilayer insulation system considered for a cuboid bipolar cable configuration of cables according to one or more embodiments of the disclosure;

FIG. 41 is an illustration of a configuration of a multilayer insulation system considered for a rectangular bipolar cable configuration of cables according to one or more embodiments of the disclosure;

FIG. 42 is an illustration of a configuration of a multilayer insulation system considered for a coaxial bipolar cable configuration of cables according to one or more embodiments of the disclosure;

FIGS. 43-44 are illustrations of a graph of an example of a comparison of cylindrical, cuboid, and rectangular bipolar cable systems in terms of weight per unit length and cross-sectional area according to one or more embodiments of the disclosure;

FIG. 45 is an illustration of a graph of an example of parameter J of four types of bipolar cable systems according to one or more embodiments of the disclosure;

FIG. 46 is an illustration of a graph of an example of radiative heat fluxes of four types of cable systems according to one or more embodiments of the disclosure;

FIG. 47 is an illustration of a graph of an example of convective heat fluxes of four types of cable systems according to one or more embodiments of the disclosure; and

FIG. 48 is an illustration of graphs of an example a magnitude of an electric field across the insulation of the bipolar cable systems according to one or more embodiments of the disclosure.

### DETAILED DESCRIPTION

Climate change is one of the most critical issues that humanity has ever faced. Greenhouse gases (GHGs) play a major role in this by trapping heat in the atmosphere, leading to a rise in global temperatures. Transportation-related GHG emissions accounted for 28% of total U.S. GHG emissions in 2021, making it the greatest producer of U.S. GHG emissions. With greater growth over the past few decades than rail, road, or shipping, aviation accounted for 2% of worldwide energy-related CO2 emissions in 2022. Given the anticipated growth in passenger and cargo air travel, commercial aircraft emissions could triple by 2050. To solve the severe climate issue and reach the goal of net-zero emissions across all sectors by 2050, it is essential to undertake significant decarbonization activities in the transportation sector. One of the most crucial strategies for meeting the goal of net zero emissions is the electrification of essential to undertake significant decarbonization activities in the transportation sector. One of the most crucial strategies for meeting the goal of net zero emissions is the electrification of transportation.

Recent studies have explored the use of electrical systems in commercial aircraft as a substitute for conventional mechanical, hydraulic, and pneumatic systems to accomplish this objective. Electric power systems (EPS) on upcoming generations of electrified aircraft, such as more electric aircraft (MEA) and all-electric aircraft (AEA), would need to be able to deliver a large quantity of power while reducing the total system mass. Power cables, being a key component of the EPS, offer significant potential for reducing the overall system mass through improvements. One possible strategy for reducing the weight of cables and, consequently, the total mass of the aircraft's EPS is to implement higher voltage operations. However, the design of cable insulation has major hurdles when dealing with higher voltage operation, and to date, there is no MVDC power cable built and tested for use at low pressures.

Designing cables for airplane applications involves several important considerations, such as partial discharges (PDs), surface charges, arc and arc tracking, and thermal management. Among these, thermal management holds utmost importance due to its substantial influence on the weight, dimensions, and maximum current capacity of the cables. These issues become considerably more significant in designing ±5 kV MVDC bipolar cables that operate in various environmental situations. When air pressure decreases, there is an increase in the intensity and frequency of PDs. Additionally, the partial discharge inception voltage (PDIV) decreases significantly, particularly at higher operating voltages. By utilizing numerous fluoropolymer layers inside insulation systems and a reasonably thick fluoropolymer layer as a jacket, problems with the arc and arc tracking are solved. Surface PDs can be mitigated through the implementation of screened insulation systems in the outer regions of the insulation system.

Due to the limited heat transfer by convection, the present power cables designed based on usual standards such as IEC 60502, which determine the material and thickness of the insulation system, are not suitable for aircraft applications. This situation is exacerbated when targeting to reduce the cable's total mass and overall diameter. To reduce the total mass of the cable, aluminum can be used instead of copper as the conductor; however, joule losses increase. Also, reducing the overall diameter of the cable results in decreasing heat transfer by radiation and convection; thus, the cable temperature exceeds its maximum permissible temperature. As a solution, by using high-temperature materials in the insulation system and increasing the temperature of the cable's surface, the reduction of heat transfer by radiation and convection can be compensated. Also, multi-layer insulation system designs can lead to a decrease in insulation system thickness regarding dielectric strength. Therefore, a multi-layer insulation system containing high-temperature materials can be a solution to reduce the total mass and overall diameter of aircraft power cables.

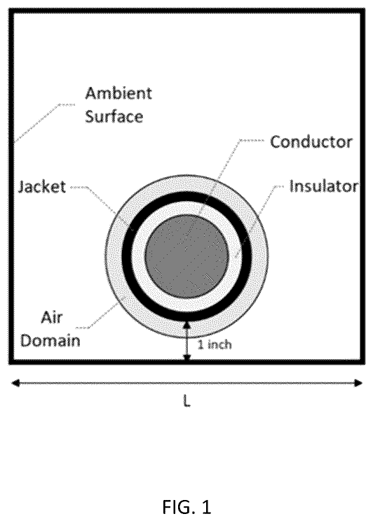

FIG. 1 illustrates a 2D finite element method (FEM) model of an EPS cable. The cable in the FEM model contains a conductor, an insulator, a copper tape screen, and a jacket. A cylindrical domain with a thickness of 0.3 inches encloses the cable to obtain natural heat convection. The thickness of the air domain is large enough to avoid the effects of boundary conditions on the temperature of the cable's surface and big enough that the solution of the natural heat convection converges. Also, a 1-millimeter-thick square shaped domain represents the ambient surface to model the heat radiation. The side of the square-shaped domain, L, is 250 mm. The steady-state heat transfer in the cable can be expressed as:

$$\frac{{T}_{core} - {T}_{S}}{{\sum }_{i = 1}^{n} {R}_{i}} = Q \qquad ( 1 )$$

$$Q = {Q}_{r} + {Q}_{c} \qquad ( 2 )$$

where T_{Core} is the conductor temperature (K), Tₛ is the cable surface temperature, Rᵢ is the thermal resistance (K·W⁻¹) of the ith insulation layer, Q is the conductor and insulation losses (W), Qᵣ is the net outward radiative heat transfer from the surface of the cable (W), and Q_{C} is the convective heat transfer from the surface of the cable to the air domain.

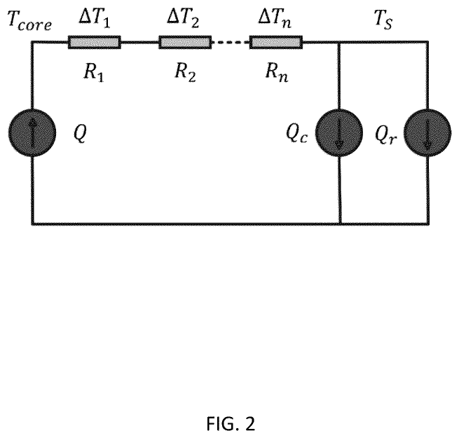

FIG. 2 shows an equivalent thermal circuit of the cable in the steady-state. The thermal resistances (Ri) is given by:

$${R}_{i} = \frac{Δ {r}_{i}}{{k}_{i} {A}_{log i}} \qquad ( 3 )$$

where k is the thermal conductivity of the ith insulation layer (W·K⁻¹·m⁻¹), Δrᵢ is the thickness of the ith layer (m), and A_{logi} is the log mean area (m) of the ith layer and can be described as:

$${A}_{log i} = \frac{{A}_{2 i} - {A}_{1 i}}{ln ( \frac{{A}_{2 i}}{{A}_{1 i}} )} \qquad ( 4 )$$

where A₂ᵢ and A₁ᵢ are outer and inner surfaces of the ith layer, respectively. Q can be described as:

$$Q = {I}^{2} R \qquad ( 5 )$$

where I (A) is the conductor current and R (Ω) is the conductor resistance. Q is influenced by the conductor's temperature as the resistivity of the conductor is a function of temperature as follows:

$${ρ}_{e} = {ρ}_{0} ( 1 + α ( {T}_{core} - {T}_{ref} ) ) \qquad ( 6 )$$

where D is the cable overall diameter (m), σ is the Stefan's constant (W·m⁻²K⁻⁴, Tₛ and T_{amb} are respectively the temperatures of the cable surface and ambient surface, and ε_{eq} is the equal emissivity and is given by:

$${ε}_{eq} = \frac{{A}_{c}}{\frac{1 - {ε}_{C}}{{ε}_{C}} + \frac{1}{{F}_{C - amb}} + \frac{1 - {ϵ}_{amb}}{{ε}_{amb} ( \frac{{A}_{C}}{{A}_{amb}} )}} \qquad ( 8 )$$

where ε_{C} and ε_{amb} are respectively the emissivity of the cable surface and ambient surface, A_{C} and A_{amb} are respectively the surface areas of the cable and ambient surface, and F_{c-amb} is the view factor and can be described as:

$${F}_{c - amb} = \frac{1}{{A}_{C}} {\int }_{{A}_{C}} {\int }_{{A}_{amb}} \frac{cos {θ}_{C} cos {θ}_{amb}}{π {R}^{2}} {dA}_{c} {dA}_{amb} \qquad ( 9 )$$

where R is the line connecting the cable surface to the ambient surface, θ_{C} and θ_{amb} are respectively polar angles formed by R with the cable surface and ambient surface, dA_{C} and dA_{amb} are elemental areas. The convective heat transfer is calculated by a coupled study of CFD and Heat Transfer modules in COMSOL Multiphysics. The steady-state heat equation in the air domain can be described as:

$$ρ {C}_{p} u \cdot ∇ T + ∇ : ( - k ∇ T ) = Q + q + τ : ∇ u \qquad ( 10 )$$

where ρ is the air density (kg·m⁻³), u is the air velocity vector (m·s⁻¹), k is the thermal conductivity of the air (W.(K.m)⁻¹), T is the temperature (K), t is the viscous tensor (Pa), and q is the heat flux (W·m⁻³). The operator “:” stands for the double dot product, which denotes a tensor contraction as defined by:

$$a : b = {\sum }_{n} {\sum }_{m} {a}_{nm} {b}_{nm} \qquad ( 11 )$$

Also, τ can be expressed as:

$$τ = μ ( ∇ u + {( ∇ u )}^{T} ) - \frac{2}{3} μ ( ∇ \cdot u ) {I}_{I} \qquad ( 12 )$$

where ρ_{ref} is the reference density (kg·m⁻³), and g is the acceleration of gravity (m·s⁻²). The main objective in designing a cable system for aerospace applications is minimizing J, which can be described as:

$$J = m \cdot D \qquad ( 15 )$$

where m is the total mass of the cable per unit length (kg·m⁻¹) and D is the overall diameter of the cable (m). Analyzing governing expressions for steady-state heat transfer in the cable and their critical parameters, a thermally desired design requires low conductor losses, large overall diameter, high thermal conductivity of insulation system, and high surface emissivity. However, low conductor losses, which means using copper instead of aluminum, and increasing the overall diameter of the cable both increase the value of J. To decrease the value of/, aluminum should be used as the conductor and the overall thickness of the cable should be reduced. To compensate for the increasing joule losses and reduction of heat transfer by radiation and convection, one can increase the surface temperature of the cable. This means using high-temperature materials with high thermal conductivity in the insulation system of the cable. Most of the insulation systems of the cables are designed based on typical standards such as IEC 60502 standard, which determines materials and thickness of the cable insulation based on the voltage level. These materials often have high dielectric strength and low thermal conductivity. Also, the maximum permissible temperature of these materials is limited to a maximum of 105° C. In this study an insulation system with low overall diameter and low total mass is designed with high temperature materials regarding these two criteria:

$${E}_{layer} < 0.8 {E}_{max} \qquad ( 16 )$$

$${T}_{layer} < {T}_{max} \qquad ( 17 )$$

where E_{layer} is the electric field of the layer, Eₘₐₓ is the dielectric strength of the layer, Tlayer is the layer temperature, and Tₘₐₓ is the maximum permissible temperature of the layer.

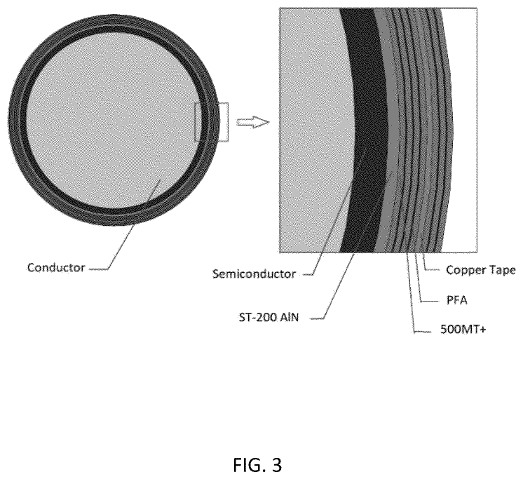

Fuse-bonded multi-layer insulation systems containing PI and PFA layers showed a great dielectric strength. Moreover, the operating temperature of both PI and PFA is higher than conventional insulation materials, with a maximum of 400° C. for PI and 260° C. for PFA. Among commercialized PI materials, thermal conductivity of DuPont™ Kapton® MT+ is higher than others. To reduce the thermal resistance of the cable insulation system, 5 mil thick DuPont™ Kapton® MT+ (500MT+) films are fuse-bonded with 1 mil thick DuPont™ Teflon® PFA films to form a multi-layer insulation system. For the first layer of the multi-layer insulation system, a 10 mil thick ST-200 AlN manufactured by Sienna Technologies, Inc. is used which has a great thermal conductivity and breakdown strength. The specifications of the designed cable system are presented in Table I. Also, the multi-layer insulation system is shown in FIG. 3.

TABLE I

| | ST-200 | | | |
|---|---|---|---|---|
| Parameters | AlN | 500MT+ | PFA | Semiconductor |
| Thermal | 180 | 0.75 | 0.195 | 10 |
| Conductivity | | | | |
| (W · (m · K)⁻¹) | | | | |
| Density (Kg · m⁻³) | 3300 | 1420 | 2150 | 1055 |
| Surface | — | 0.88 | — | — |
| Emissivity | | | | |
| Dielectric | >70 | 115 | 260 | — |
| Strength | | | | |
| (kV · mm⁻¹) | | | | |
| Relative | 8.5 | 3.5 | 2 | — |
| Permittivity | | | | |

Thermal and electrical characteristics of the designed cable are compared to typical designs based on IEC standard for copper and aluminum 1350 conductors. In the designs based on IEC standard, TRXLPE and PE are chosen as insulator and jacket, respectively. The thermal and electrical characteristics of designed cables based on the IEC standard are presented in Table II. The maximum temperature of the cables with the IEC standard design is determined by the maximum permissible temperature of the insulation system. However, for the multi-layer insulation system, the maximum temperature of the cable is determined by the maximum permissible temperature of aluminum 1350, which is 170° C. In Table III, the maximum permissible temperature, the conductor's diameter, overall diameter of the cable, overall weight of the cable per unit length, maximum electric field, and J are presented for IEC-based and multi-layer cable system designs for the ambient temperature of 40° C. and ambient pressure of 18.8 kPa when the conductor current is 1000 A, and the temperatures of the cables reach their maximum permissible temperature. To obtain steady-state, the simulation time in COMSOL Multiphysics is set to 30 hours. The overall diameter of the multi-layer cable system is reduced by 27.8% and 36.9% compared to the copper and aluminum cables designed based on IEC standard, respectively. Also, the overall weight of the multi-layer cable is decreased by 70.6% and 47.7% compared to the copper and aluminum cables designed based on IEC standard, respectively. The value of J for multi-layer cable is reduced by 78.8% and 67% compared to the copper and aluminum cables designed based on IEC standard, respectively. Moreover, the maximum electric field across the insulation of the multi-layer cable is 8.4 kV/mm, which is smaller than 0.8 of the dielectric strength value of materials used in the multi-layer insulation system, so the designed cable is electrically safe to operate.

TABLE II

| Parameters | TRXLPE | PE | Semiconductor |
|---|---|---|---|
| Thermal | 0.286 | 0.286 | 10 |
| Conductivity | | | |
| (W · (m · K)⁻¹) | | | |
| Density (Kg · m⁻³) | 960 | 935 | 1055 |
| Surface | — | 0.91 | — |
| Emissivity | | | |
| Relative | 2.5 | 2.5 | — |
| Permittivity | | | |

TABLE III

| | | Aluminum | Aluminum 1350, |
|---|---|---|---|
| | Copper, | 1350, IEC | Multilayer |
| Parameter | IEC design | design | design |
| Maximum | 105 | 105 | 170 |
| Temperature (° C.) | | | |
| Conductor's | 2.2352 × 10⁻² | 2.7305 × 10⁻² | 2.07 × 10⁻² |
| Diameter (m) | | | |
| Overall Diameter | 3.4553 × 10⁻² | 3.9541 × 10⁻² | 2.4942 × 10⁻² |
| (m) | | | |
| Overall Weight | 4.1462 | 2.3251 | 1.2169 |
| (kg · m⁻¹) | | | |
| Maximum | 1.82 | 1.81 | 8.4 |
| Electric Field | | | |
| (kV/mm) | | | |
| J (kg) | 14.33 × 10⁻² | 9.19 × 10⁻² | 3.035 × 10⁻² |

A multi-layer high-temperature insulation system for an MVDC power cable for the future wide-body all-electric aircraft is designed and analyzed for the first time by developing a coupled model including thermal, electrical, and computational fluid dynamic (CFD) physics. As a result, the designed multi-layer cable's overall diameter and mass using aluminum 1350 for its core decreased by 27.8% and 70.6% compared to a copper cable designed based on IEC 60502 standard (single-layer insulation), respectively. Also, the overall diameter and mass of the designed multi-layer cable are 36.9% and 47.7% decreased compared to the cable using aluminum 1350 for its core and single-layer insulation designed based on the IEC 60502-2 standard.

A higher risk of arcing in cable systems results from operating at higher voltage levels, higher dv/dt, higher power density, and decreased wire distances. Arc tracking could happen by turning the polymer surface into a conductive path, increasing the risk of an arc or total breakdown. Arc tracking refers to the arcing process in which an electric current produces carbonization. While the ambient and network conditions have a significant impact on the arcing phenomena, the insulation's chemical composition has a greater impact on tracking susceptibility. Although arc tracking can be produced by contaminants, radial cracking, imprint labeling, abrasion by rubbings, and short circuits, the main reason for arc tracking is PDs. Arc tracking can be divided into two categories: wet arc tracking and dry arc tracking. For aircraft cables, wet arc tracking can happen when moisture or fluids from the aircraft cause a short circuit between two exposed wires that are next to each other or between an exposed wire and the aircraft structure at different electric potentials. Dry arc tracking is mainly caused by poor installation techniques, insulation degradation, and abrasion caused by aging polymeric insulating materials and environmental stresses including UV radiation from sunshine, and moisture, leading to a short circuit between the cable and surrounding environments such as neighboring wires and aircraft structures. Dry arcing generated by nearby carbonized areas promotes thermal degradation, thus producing tracking and erosion.

Copper wires with polytetrafluoroethylene (PTFE) fluorocarbon polymer insulation are the classic method for preventing arc tracking. However, using copper as the conductor is an obstacle to meeting the low-system-mass requirement for aircraft EPS. It has been shown that for cables with the same nominal ampacity, the erosion speed for the copper cables is greater than aluminum cables due to the larger value of linear density of aluminum cables. This means the length of damaged parts of the cable, which depends on the erosion speed, for cables with the same nominal ampacity is smaller for aluminum cables compared to copper, while it is greater for the same size of the conductor and insulation. Thicker insulation help reduce the arc's damage since lesser erosion speed is observed in cables with thicker insulation. Thus, regarding arc and arc tracking, using aluminum with a proper insulation system is reasonable for aircraft cabling.

There are no plastics or polymers completely resistant to arc tracking. Most aromatic polymers (PI and Kapton®), thermoset plastics, and materials including alternating double bonds are prone to carbonization, thus more inclined to arc tracking. However, aliphatic fluoropolymers are more resistant to producing carbon deposits owing to heat degradation, so they may withstand wet arc tracking. Some polyimide insulation such as Kapton® may be enhanced to withstand wet arc tracking by using thin fluoropolymer coatings such as PTFE (Teflon®). However, aged Kapton® is more vulnerable and brittle mechanically, so it is more likely to generate cracks in the insulation and causes dry arc tracking occurrence. Compared to wires with PI insulation, those with fluoropolymers such as ETFE and PTFE, are more resilient against a fault arc. However, it was shown that insulation systems with higher PI ratios exhibit higher breakdown voltages. It is worth mentioning that multi-layer insulation systems including multiple (>3) layers of PI and fluoropolymer exhibit significantly higher dielectric strength compared to fluoropolymer/PI/fluoropolymer insulation systems (3 layers) such as TKT and Teflon® PFA/Kapton®/Teflon® PFA. Therefore, an optimized design for insulation systems to prevent arc and arc tracking while fulfilling higher breakdown voltages is to use both PI and fluoropolymer polymers in the insulation system. Both fluoropolymer and polyimide polymers are used in designing multilayer multi-function insulation systems with a special high temperature aluminum as a core conductor for ±5 kVdc, 1 kA cable capable of working in harsh aviation environments.

Considering air discharge initiation and evolution process, electrical systems operating at lower pressures can generate more partial discharge than ones operating at atmospheric pressure. The moisture condensation during the rapid ascent and descent of aircraft exacerbates the occurrence of PD. As the air pressure decreases, both the magnitude and number of PD increase, and PD inception voltage (PDIV) decreases especially for higher operating voltages. Also, PDIV decreases when the frequency of the applied voltage increases. As mentioned before, PD is the main reason for arc tracking. Surface PD activities on an organic material break down the polymer and cause it to move from an insulator to a conductor due to strong thermal shocks produced by an intense bombardment of electrons. Ultimately, this results in the generation of carbonized conducting paths causing a disruptive discharge or total breakdown. Aircraft cables can be screened or unscreened. The insulation part in the screened cables can be developed without considering objects in the proximity of the cable, whereas for unscreened cables the objects in the proximity of the cable should be considered. For an air pressure of 10 kPa, increasing the thickness of the insulation or decreasing the relative permittivity of the insulation results in increasing PDIV. However, this trend is not linear, suggesting that to achieve a high-power density and low system mass EPS at higher voltages, either screened cables or using corona-barrier materials in the insulation system of unscreened cables must be considered to manage the insulation thickness. The corona-barrier materials show higher amounts of the Hours to Failure in PD tests compared to other conventional materials used in cable insulation systems. Although, using corona-barrier materials in the outer layers of power cables cannot completely prevent the possibility of a failure due to the PDs between the cable and objects in its vicinity, it provides a longer duration to reach the failure, thus experiencing relatively higher prevention of total failure. Therefore, to tackle PDs' challenges, these materials can be implemented into the cable insulation systems instead of increasing the thickness of the insulation or using materials with lower relative permittivity. Insulation systems with screen or corona barrier materials are developed and analyzed to eliminate or minimize PD's effects on the cable.

Among challenges in designing MVDC power cables for envisaged wide body all electric aircraft, thermal management is of great importance since the strongly limited convection at a low air pressure of 18.8 kPa at wide-body aircraft cruising altitude (12.2 km), has a considerable impact on heat transfer. Consequently, in comparison to atmospheric pressure, the maximum permissible current flowing through the cable decreases. Also, the electric field distribution across the DC cables depends on conductivity, which in turn relies on temperature. Therefore, determining the temperature field across the cable is crucial for obtaining the electric field across the insulation part of DC cables. Additionally, the conductivity gradient across the insulation, which is dependent on the temperature differential, contributes to the accumulation of the space charge. The distribution of the electric field is impacted by the accumulation of space charge, which might lead to dielectric failure and deterioration. In polymeric insulating materials, the rate of space charge accumulation will increase over their electric field threshold. To maintain a safe and dependable longer service life for DC cables, it is essential to keep the electric field in the cable below its threshold. However, the electric field threshold decreases for polymeric materials by increasing the temperature. Consequently, determining the temperature field throughout the cable provides insight into designing DC cables with the extremely high degree of safety and dependable long-life operation necessary in airplanes. Power cables designed based on IEC 60502 standard based on single-layer insulation cannot be used for high-power-density and low system-mass targets in aircraft due to their higher size and mass.

Several designs for the insulation system of a ±5 kVdc, 1 kA aircraft cable with a core conductor of a special high-temperature aluminum are for the first time designed through a coupled thermally, electrically and fluid dynamics model elaborated in COMSOL Multiphysics. Designs must be examined thermally and electrically to be evaluated in terms of their mass and size, since the target is designing high power-density and low-system mass cable systems.

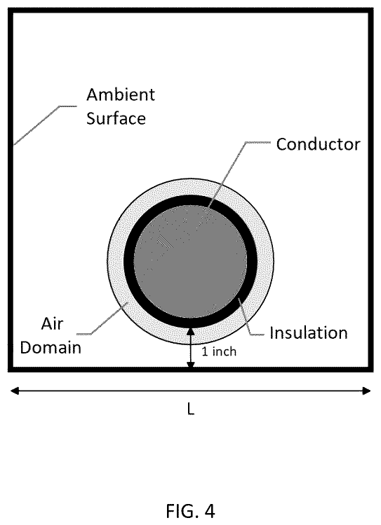

A coupled electrical, thermal, and fluid flow dynamics model is needed to study the electrical and thermal performance of different designs of aircraft MVDC power cables working at 18.8 kPa. FIG. 4 shows the geometry considered in this study. It is required that an adequate separation between the cable and other parts of the airplane exists so that cable failure will not create hazardous effects on the airplane or its systems. Therefore, the cable is placed in a square-shaped duct as shown in FIG. 1 and based on recommendations on post insulators at a distance of 1 inch from the bottom of the duct. A 0.35-inch-thick cylindrical air domain is considered to enclose the cable to achieve natural heat convection. The thickness of the air domain is large enough that the effects of open boundary on the cable surface temperature can be neglected and small enough to converge the natural heat convection solution. The temperature of the outer boundary of the air domain equals the ambient temperature. To include the heat transfer by radiation, the duct is assumed to be made from aluminum alloy with a thickness of 1 mm, and its temperature is equal to the ambient temperature. The voltage of the cable is 5 kVdc and its ampacity is 1000 A. The ambient temperature is 40° C., and the pressure of the air inside the duct is 18.8 kPa, resembling the air pressure at cruising altitude of a wide-body aircraft.

The heat equation in the core conductor of the cable to its surface can be expressed as:

$$ρ {C}_{p} \frac{\partial T}{\partial t} + ∇ \cdot ( - k ∇ T ) = Q + {q}_{o} \qquad ( 18 )$$

where ρ is the density (kg·m⁻³), Cₚ is the specific heat capacity at the constant pressure (J.(kg.K)⁻¹), k is thermal conductivity (W.(K.m)⁻¹), T is the temperature (K), and q₀ is the net outward radiative heat flux (W·m⁻³). Q is the heat source (W·m⁻³) resulting from joules losses and can be described as:

$$Q = {I}^{2} R \qquad ( 19 )$$

where I is the conductor current (A) and R is the conductor resistance (Ω).

Due to the cylindrical shape of the cable, considering P₁ is a point located on the surface of the cable, the net outward radiative heat flux (q₀) at P₁ is given by:

$${q}_{o} = {ε}_{1} ( {E}_{b 1} ( T ) - {G}_{12} ) \qquad ( 20 )$$

where ε₁ is the emissivity of the cable surface, G₁₂ is the irradiation received at point P₁ from the ambient surface (W·m⁻²), and E_{b1}(T) is the power radiated across all wavelengths (W·m⁻²) from P₁. For details about G₁₂ and E_{b1}(T).

The heat equation in the air domain can be described as:

$$ρ {C}_{p} \frac{\partial T}{\partial t} + ρ {C}_{p} u \cdot ∇ T + ∇ \cdot ( - k ∇ T ) = Q + q + τ : ∇ u + \frac{- T}{ρ} \frac{\partial ρ}{\partial t} ( \frac{\partial ρ}{\partial t} + u \cdot ∇ P ) \qquad ( 21 )$$

where ρ is the air density (kg·m⁻³), Cp is the heat capacity at the constant pressure of the air (J.(kg.K)⁻¹), u is the air velocity vector (m·s⁻¹), k is the thermal conductivity of the air (W.(K.m)⁻¹), T is the temperature (K), τ is the viscous tensor (Pa), q is the heat flux (W·m⁻³) and P is the pressure (Pa). The operator “:” stands for the double dot product.

The fluid (here air) velocity field can be determined from the momentum equation and the equation of continuity that are respectively expressed as:

$$ρ \frac{\partial u}{\partial t} + ρ ( u \cdot ∇ ) u = ∇ \cdot ( - {PI}_{I} + τ ) + ( ρ - {ρ}_{ref} ) g \qquad ( 22 )$$

$$\frac{\partial ρ}{\partial t} + ∇ \cdot ( ρ u ) = 0 \qquad ( 23 )$$

where ρ_{ref} is the reference density (kg·m⁻³), and g is the acceleration of gravity (m·s⁻²). The electric field in polymeric DC cables is a strong function of conductivity. In turn, conductivity depends on temperature field, electric field, and material of the insulation. Generally, DC conductivity of polymers can be expressed by empirical formulas such as:

$$σ ( E , T ) = {σ}_{0} {e}^{- \frac{a}{T} + bE} \qquad ( 24 )$$

$$σ ( E , T ) = A exp ( \frac{- ϕ {q}_{e}}{{k}_{b} T} ) \frac{sinh ( B ( T ) ln ( E ) )}{{E}^{γ}} \qquad ( 25 )$$

where E is the electric field (V·m⁻¹), a is the temperature coefficient, b is the electric field coefficient, φ is the thermal activation energy, qₑ is the electron charge, and k_{b} is Boltzmann's constant. σ₀, A and γ are polymeric material related constants, and B(T) is given by:

$$B ( T ) = cT + d \qquad ( 26 )$$

where c and d are polymeric material-based constants. The electric field distribution can be obtained by

$$E = - ∇ V \qquad ( 27 )$$

$${J}_{e} = σ E \qquad ( 28 )$$

where V is the voltage (V), Jₑ is the current density (A·m⁻²), and σ is the conductivity (S·m⁻¹). Also, the space charge density in the steady state can be calculated using:

$$σ E \cdot ∇ ( \frac{{ϵ}_{e}}{σ} ) = {ρ}_{e} \qquad ( 29 )$$

where εₑ is the permittivity and ρₑ is the space charge density. Using equations (24), (27), and (28) the electric currents module in COMOSL calculates the electric field distribution across the insulation, and by solving the equation (29) space charge accumulation across the bulk of the insulation is obtained. The determined electric field distribution by electric currents module includes both electric fields due to the potential of the core conductor and the space charge accumulation. As seen from equations (18)-(29), the temperature field, velocity field, and electric field are coupled. The COMSOL Multiphysics is used to handle the aforementioned equations. To obtain the steady case, the simulation time is 30 hours.

Having the coupled electrical, thermal, and fluid flow dynamic model developed above, we define the optimal design of aircraft MVDC power cables to achieve minimum overall thickness and weight of the cable. In this regard, J is defined as:

$$J = m \cdot D \qquad ( 30 )$$

where m is the total mass of the cable per unit length (kg·m⁻¹) and D is the overall diameter of the cable (m). The smaller/the more desirable design, which means towards high-power density and low-system-mass requirements. J can be minimized by employing a particular type of high-temperature aluminum and a multi-layer insulation system for the core and insulation parts of a targeted ±5 kV, 10 MW aircraft cable. In this regard, for a multi-layer insulation system, the designs should meet the following electrical and thermal requirements for i^{th} dielectric layer:

$$\begin{matrix}Emax ( i ) < 0.8 Ebd ( i ) & i = 1 : n\end{matrix} \qquad ( 31 )$$

$$\begin{matrix}Tmax ( i ) < Tlimit ( i ) & i = 1 : n\end{matrix} \qquad ( 32 )$$

where Eₘₐₓ₍ᵢ₎ and E_{bd(i)} are maximum electric field and breakdown strength of i^{th} dielectric layer, respectively, and n is the number of dielectric layers. Tₘₐₓ₍ᵢ₎ and Tₗᵢₘᵢₜ₍ᵢ₎ are the maximum temperature and permissible temperature of i^{th} dielectric layer, respectively. For the core conductor:

$$T max ( core ) < T limit ( core ) \qquad ( 33 )$$

where T_{max(core)} and T_{limit(core)} are the maximum temperature and permissible temperature of the considered core conductor, respectively.

Emax(i), Tmax(i), and Tmax(core) amounts are obtained using the model developed above. E_{bd(i)}, Tₗᵢₘᵢₜ₍ᵢ₎, and T_{limit(core)} are obtained from the datasheet of the considered materials. This is a highly complex problem where the goal is to determine the material and radius of core conductor, along with the arrangement, type, and thickness of different insulation layers, to minimize/while meeting equations (30)-(32) for a 5 kVdc, 1 kA cable located in the geometry shown in FIG. 4 where the model described above is used to derive temperature and electric field distributions across a cable with a temperature and pressure inside the duck of 40° C. and 18.8 kPa, respectively.

The following points should be considered when choosing materials for the insulation layers and core conductor of aviation power cables. Using aluminum instead of copper for the core conductor results in lighter cables. Also, as mentioned before, for the same nominal capacity, the length of damaged parts caused by an arc is smaller for aluminum cables compared to copper ones. Thus, to achieve high-power-density and low system-mass aircraft cables, aluminum is chosen as the core conductor for the designed cables. For designing aircraft power cables, challenges regarding arc and arc tracking, PD, and thermal management for long reliable operation should be considered. To this end, any insulation design must contain fluoropolymers layers to prevent arc and arc tracking, be resistant against surface PD either by being screened or using corona-barrier materials, and be thermally optimized regarding the low-pressure and possible high-temperature environment of cable duct to fulfill the requirements of a reliable long-life operation.

State-of-art designs for aircraft power cables existing in the market mainly use insulation materials made of Tefzel®, TKT (Teflon®/Kapton®/Teflon®), and PTFE/Polyimide/PTFE with coated copper conductor. However, these cables designed based on AS22759 are for a maximum nominal voltage of 600 Vrms while our goal is to design aircraft power cables for DC (not AC) at a voltage and current level (±5 kV, 1 kA) much higher than that for AS22759. On the other hand, IEC 60502 standard is for designing non-aviation power cables up to 30 kVrms.

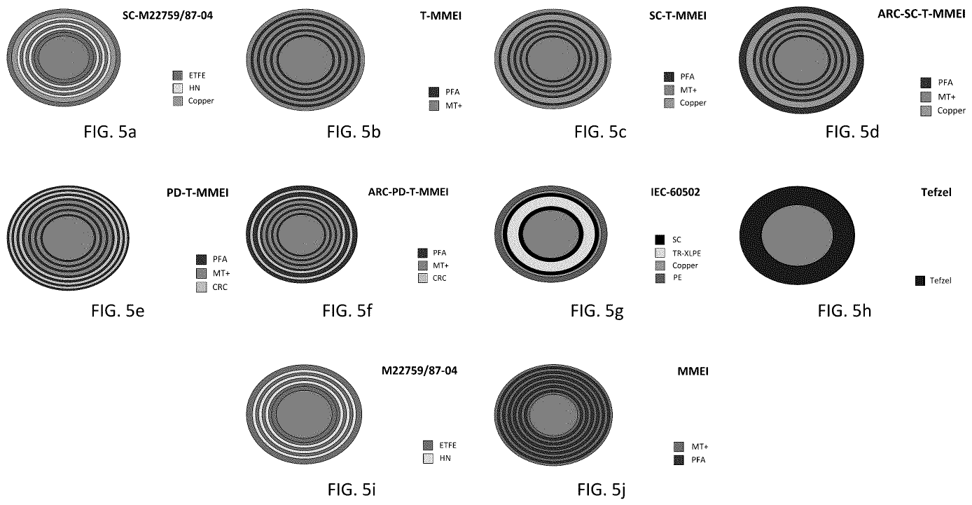

Six disclosed insulation systems for our cable are termed as SC-M22759/87-04, T-MMEI, SC-T-MMEI, ARC-SC-MMEI, PD-T-MMEI, and ARC-PD-T-MMEI, shown schematically in FIGS. 5a-5f, respectively. To design thermally optimized insulation systems, materials with high thermal conductivity must be used. To this mean, in this study, Kapton® MT+ is used because of its higher thermal conductivity compared to other polyimide polymers. Moreover, Kapton® MT+ has a high dielectric strength. However, Kapton® MT+ is a polyimide material prone to arc and arc tracking. To include arc prevention, Teflon® PFA is used which is a fluoropolymer material as a jacket. Also, for corona-barrier functionality, Kapton® CRC, which is a corona-resistant film, is used in two of the disclosed cable systems.

It has been shown that using wrapped layers of polyamides and fluoropolymer films shows higher breakdown voltage compared to conventional single-layer insulation systems. Therefore, a multi-layer, multi-function electrical insulation (MMEI) structure for the insulation part of the cable is used.

The SC-M22759/87-04 is designed to compare designed insulation systems with a screen layer to M22759/87-04. This configuration contains a screen layer of copper with a thickness of 5 mils between the middle layer and the outer layer of M22759/87-04. The T-MMEI is a thermally optimized version of MMEI and consists of 12-mil wrapped layer of Teflon® PFA (0.5-mil film) and Kapton® MT+ (1.5-mil film). The SC-T-MMEI, ARC-SC-T-MMEI, PD-T-MMEI, and ARC-PD-TMMEI contain the same inner layer of 6.5-mil wrapped Kapton® MT+ (1.5-mil film) and Teflon® PFA (0.5-mil) layer, however, the outer layer of SC-T-MMEI, which exhibits screening besides being thermally optimized, is a 5-mil copper tape, 2-mil layer of Teflon® PFA (0.5-mil film) and Kapton® MT+ (1.5-mil film). The ARC-SC-T-MMEI exhibits arc prevention besides screening and being thermally optimized. This design includes a 5-mil thick copper and 4-mil thick Teflon® PFA jacket on the outer layer. The PD-T-MMEI experiences corona-barrier and thermally optimized multifunctionalities, where its outer layer is a 4.5-mil thick wrapped layer of Teflon® PFA (0.5-mil film) and Kapton® CRC (1-mil film). The ARC-PD-T-MMEI exhibits arc-preventing, corona barrier, and being thermally optimized. The outer layer of ARCPD-T-MMEI is a 6 mil wrapped layer of Teflon® PFA (2-mil film) and Kapton® CRC (1-mil film).

Table IV presents the multifunctionality of the insulation systems regarding preventing arc and PD, shielding EMI, and being thermally optimized. As presented in Table IV, ARC-SCT-MMEI exhibits the most multi-functionalities required for cable systems operating in aircraft applications. Also, Table V presents the density, thermal conductivity, dielectric constant, and dielectric strength of the material used in designing insulation systems of Table IV.

TABLE IV

| | Maximum | | | | |
|---|---|---|---|---|---|
| | Temper- | | | | |
| | ature | | | | |
| Cable | (° C.) | Arc | Thermal | PD | EMI |
| IEC 60502 | 105 | — | — | screened | screened |
| Tefzel ® | 150 | preventing | — | — | — |
| M22759/87- | 260 | preventing | — | — | — |
| 04 | | | | | |
| MMEI | 260 | — | — | — | — |
| SC-M22759/ | 260 | preventing | — | — | screened |
| 87-04 | | | | | |
| T-MMEI | 260 | — | optimized | — | — |
| SC-T-MMEI | 260 | — | optimized | screened | screened |
| ARC-SC-T- | 260 | preventing | optimized | screened | screened |
| MMEI | | | | | |
| PD-T-MMEI | 260 | — | optimized | barrier | — |
| ARC-PD-T- | 260 | preventing | optimized | barrier | — |
| MMEI | | | | | |

TABLE V

| | | Thermal | | |
|---|---|---|---|---|
| | Density | Conductivity | | Dielectric |
| | (kg · | (W · m⁻¹ · | Dielectric | Strength |
| Material | m⁻³) | K⁻¹) | Constant | (V · m⁻¹) |
| Tefzel ® | 1700 | 0.24 | 2.6 | 157.5 × 10⁶ |
| Kapton ® HN | 1420 | 0.2 | 3.4 | 303 × 10⁶ |
| Teflon ® PFA | 2150 | 0.195 | 2 | 256 × 10⁶ |
| Kapton ® MT+ | 1420 | 0.75 | 4.2 | 208.5 × 10⁶ |
| Copper | 8960 | 400 | — | — |
| Kapton ® CRC | 1550 | 0.2 | 3.4 | 256 × 10⁶ |
| TRXLPE | 960 | 0.286 | 2.5 | 196.8 × 10⁶ |
| PE | 935 | 0.286 | 2.5 | 196.8 × 10⁶ |
| Semiconducting | 1055 | 10 | — | — |

Considering Kapton® HN, Kapton® MT+, Kapton® CRC as PI materials, and Teflon® PFA as an ETFE material, the electrical conductivity of the material used in the designed cables was calculated by curve fitting of data from and equation (24). Table VI presents the parameters of the electrical conductivity for PI and ETFE materials. The σ₀ of ETFE is smaller than its value of PI, indicating that the electrical conductivity of PI is larger than ETFE. Also, the electric field coefficient, b, of PI is larger than ETFE which means that the sensitivity of the conductivity of PI to the electric field norm is larger than ETFE. Moreover, the coefficient of temperature, a, is larger for ETFE, showing that the sensitivity of the conductivity of ETFE to temperature is larger for ETFE compared to PI.

TABLE VI

| Parameter | σ₀ (S/m) | a (K) | b (mm/kV) |
|---|---|---|---|
| PI | 1.677e−9 | 3319 | 0.05558 |
| ETFE | 2.027e−10 | 4061 | 0.03097 |

Table VII presents minimum diameter of the core conductor, minimum diameter of the cable including its core and insulation system, weight per unit length of the cable, and J of the disclosed cable systems described above when the conductor's current is 1000 A, duct temperature is 40° C., and the duct pressure is 18.8 kPa. The voltage of the core conductor is ±5 kV. The geometry considered for studies is shown in FIG. 4 with L=250 mm. In order to obtain these optimal designs of cables with the lowest amount of J under the mentioned working and environmental conditions, many simulations were run.

As a comparison, a cable based on IEC 60502 and AS22759 is disclosed under the mentioned working and environmental conditions. The IEC 60502 design consists of semiconducting and TRXLPE insulation, 5-mil copper tape screen, and PE jacket, schematically shown in FIG. 5g. The Tefzel® insulation system which is based on AS22759 standard consists of one layer of Tefzel®, schematically shown in FIG. 5h.

Also, the insulation of M22759/87-04, schematically shown in FIG. 5i, which is based on AS22759 is analyzed due to its comparable conductor size to the disclosed designs. The M22759/87-04 insulation system consists of 2-mil Teflon® PFA film as inner layer, 6-mil wrapped layers of Teflon® PFA (1-mil film) and Kapton® HN (1-mil film) in the middle, and 4-mil Teflon® PFA film as outer layer.

Also a MMEI cable, shown as MMEI in Table VII, which includes of 12-mil wrapped layer of Kapton® HN (1-mil film) and Teflon® PFA (1-mil film) and a 1-mil Kapton® HN film as the outer layer and schematically shown in FIG. 5j was designed.

The IEC 60502 design shows a significantly huge amount of J compared to other investigated cable systems. Also, the Tefzel® design exhibits a higher/mainly because of its lower maximum operating temperature compared to other designs. Also, the M22759/87-04 has a smaller amount of J compared to the MMEI structure. Among screened designs, the SC-T-MMEI experiences the smallest amount of/, but a roughly larger J compared to M22759/87-04. However, the SC-T-MMEI meets screening with PD prevention and EMI shielding multi-functionalities, which the M22759/87-04 lacks to possess. To better understand the difference between the M22759/87-04 cable and the SC-TMMEI, the SC-M22759/87-04 has been modeled which is an improved version of the M22759/87-04 cable with the same size screen. The value of J is, 3.7% lower for SC-T-MMEI compared to SC-M22759/87-04. Moreover, SC-T-MMEI has an 86.3% lower J compared to IEC 60502 design. Although the ARC-SCT-MMEI shows a 0.8% higher J compared to the SC-T-MMEI, due to its 4-mil fluoropolymer jacket, it has a good tolerance against arc and arc tracking, thus increasing the multifunctionality of the cable system.

TABLE VII

| | Core | | | |
|---|---|---|---|---|
| | Conductor | Cable | Weight per | |
| | Diameter | Diameter | unit length | |
| Cable System | (mm) | (mm) | (kg · m¹) | J (g) |
| IEC 60502 | 27.41 | 39.64 | 2.3421 | 92.841 |
| Tefzel ® | 22.71 | 23.34 | 1.1342 | 26.472 |
| M22759/87-04 | 17.27 | 17.88 | 0.6669 | 11.924 |
| MMEI | 17.4 | 18.06 | 0.6755 | 12.200 |
| SC-M22759/87-04 | 17.25 | 18.11 | 0.7287 | 13.197 |
| T-MMEI | 17.22 | 17.83 | 0.6570 | 11.714 |
| SC-T-MMEI | 17.20 | 17.88 | 0.7107 | 12.707 |
| ARC-SC-T-MMEI | 17.15 | 19.93 | 0.7144 | 12.809 |
| PD-T-MMEI | 17.17 | 17.73 | 0.6522 | 11.564 |
| ARC-PD-T-MMEI | 17.20 | 17.83 | 0.6595 | 11.759 |

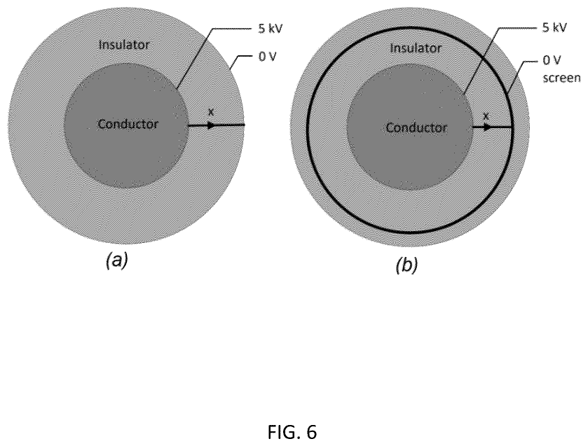

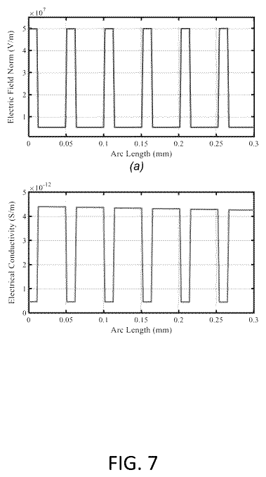

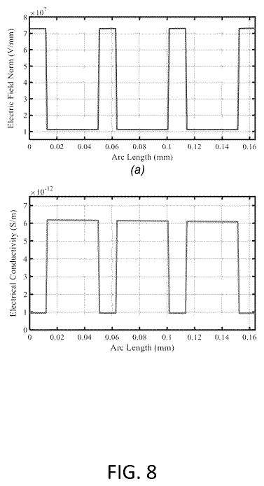

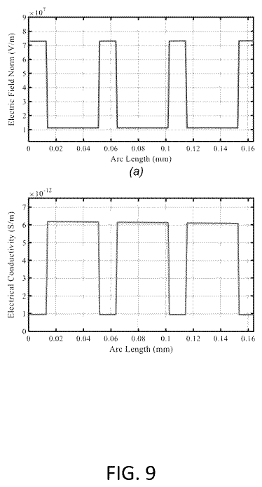

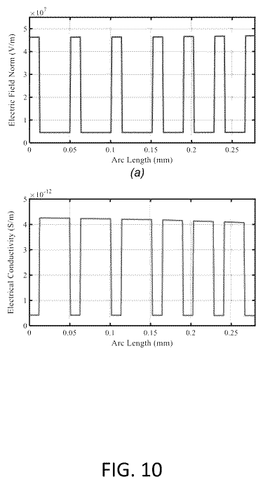

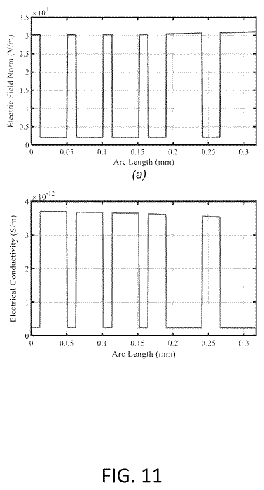

The PD-T-MMEI has the smallest amount of J among designed cables. The PD-T-MMEI exhibits 87.5%, 3%, and 5.2% lower J compared to the IEC 60502, the M22759/87-04, and the MMEI designs, respectively. However, the PD-T-MMEI lacks to show EMI shielding and preventing arc tracking besides other multi-functionalities. While the ARC-PD-T-MMEI shows 1.7% higher/compared to the PD-T-MMEI, it contains a fluoropolymer with corona-barrier jacket, thus regarding multi functionalities is preferred, as Table IV presents. The ARC-PD-TMMEI shows 87.3%, 1.3%, and 3.6% lower J compared to IEC 60502, M22759/87-04, and MMEI designs. By comparing the value of/in Table VII, it can be concluded that increasing the maximum permissible temperature of the insulation system decreases the J, significantly. Also, increasing the number of functionalities of the designed cables comes with the cost of a higher J. Moreover, the screen layer increases the total weight of the cable in comparison to corona barrier layer, since the screens are mostly metallic material with higher density and weight than polymers. These points can be used for future designs of aircraft cables. For screened cables, the screen is grounded. Also, for unscreened cables, the surface of the cable (outer boundary of the outset layer) is grounded. FIG. 6 illustrates which parts of the insulation systems are placed between those two potentials for screened and unscreened cables, and the definition of x as the minimum distance between two different potentials. FIGS. 7-11 show the electric field norm and the electrical conductivity across the insulation of the designed cables. The maximum of x depends on the maximum insulation thickness that is placed between the two different potentials. For the T-MMEI the x is about 0.3 mm. Since the insulation configuration between the conductor and the screen for both SC-T-MMEI and ARC-SC-T-MMEI is the same, the x for these designed cables is the same and is about 0.16 mm. Moreover, the x for PD-T-MMEI and ARC-PD-T-MMEI is about 0.27 mm and 0.31 m, respectively. The electric field distribution across the designed cables is calculated using expressions (24), (27), and (28). The calculated electric fields are a sum of those resulting from the potential of the core conductor and space charges formed across the insulation systems due to a small current density between the two different potentials (5 kV and 0 V) and space charge accumulation at the steady state. These calculated fields mostly depend on the conductivity of the insulation materials. The electrical conductivity of the PFA and ETFE layers are lower than that of the Kapton® HN, Kapton® MT+, and Kapton® CRC meaning that the electric field norm across the ETFE and Teflon® PFA layers is larger than PI layers. The electric field inversion is observed in PFA and ETFE layers, especially in the PD-T-MMEI and the ARC-PD-T-MMEI designs, due to their larger coefficient of temperature compared to PI layers. The electric field inversion refers to when the electric field norm across a cylindrical insulation is smaller at smaller radii than larger ones. This phenomenon occurs due to a temperature gradient across the insulation system. A higher temperature yields a larger electric conductivity of a material at smaller radii (closer to the conductor), resulting in a smaller electric field norm, compared to parts of the material with larger radii and lower temperatures. The SC-T-MMEI and the ARCSC-T-MMEI show the largest electric field norm mainly due to their smaller insulation thickness compared to other designed cables. Nevertheless, the electric fields across the insulation system of the designed cables are less than 80% of the dielectric strength of the constituting materials, meeting Eq. (30) and indicating the designed cables are electrically safe to operate. Although PI layers are added to PFA layers to increase the total breakdown voltage of the insulation systems, due to lower electric conductivity, the PFA layers experience higher electric stress. Therefore, there is a careful need in considering the electric conductivity of the materials that are used in designing aircraft cables. Choosing materials with approximately the same electric conductivity results in a smoother electric field distribution across and between the layers, and prevents the possibilities of further issues, such as internal PDs in voids between the layers.

Several aircraft MVDC power cables are disclosed to meet environmental aviation challenges, including arc and arc tracking, PD, and thermal management, while maintaining high-power-density and low-system-mass requirements for envisaged wide-body all-electric aircraft. The designed cable systems are analyzed thermally and electrically and compared to designs based on current standards such as IEC 60502 and AS22759. Thermal and electrical analysis of the cables was conducted using a coupled electric, thermal, and fluid flow dynamic model. The model included all possible heat transfer approaches, including conduction, convection, and radiation. J is introduced to evaluate the disclosed cables, which is the product of the cables' overall mass per length and diameter. The results show that the thermally optimized MMEI cable system with PD barrier layers, PD-T-MMEI, exhibits a 87.5%, 3%, and 5.2% lower J compared to IEC 60502, M22759/87-04 which is a design based on AS22759, and MMEI designs. Also, the screened thermally optimized MMEI design, SC-T-MMEI, introduced which shows a roughly higher amount of/compared to design based on AS22759, while has PD prevention and EMI shielding capabilities, which the AS22759 design lacks to exhibit. The SC-T-MMEI cable system experiences 3.7% and 86.3% lower/compared to SCM22759/87-04, screened version of AS22759 design, and IEC 60502 design, respectively.

Moreover, two designs are disclosed to tackle arc tracking and PD in aircraft applications, ARC-SC-T-MMEI and ARC-PD-T-MMEI. The ARC-PD-TMMEI shows 87.3%, 1.3%, and 3.6% lower J compared to IEC 60502, M22759/87-04, and MMEI designs; while this design experiences 1.7% higher J compared to PD-T-MMEI, it prevents arc tracking, so more suitable for aircraft applications. The ARC-SC-T-MMEI exhibits a slightly higher amount of J compared to M22759/87-04 and MMEI, and a smaller amount of/compared to SC-22759/87-04. The ARC-SC-T-MMEI design experiences multiple functionalities such as preventing arc tracking, being thermally optimized, PD preventing, and EMI shielding capabilities which are critical for MVDC power cables in aircraft applications. Moreover, the electric field norm across the designed cables is examined, and shown that the designed cables are safe to operate at the voltage level of 5 kVdc.

Increasing the voltage level of the aircraft EPSs to medium voltages exacerbates critical challenges in designing power cables for aircraft applications such as arc and arc tracking, partial discharge (PD), surface charges, and thermal management. Arcs that develop in aircraft's EPSs might have devastating effects; as a result, they should be prevented or mitigated as much as possible. Electrical systems operating at lower pressures than those running at atmospheric pressure can produce a higher rate and magnitude of PD and show smaller PD inception voltage (PDIV) when considering the air discharge initiation and evolution process. Surface charges on some insulating materials may create electrostatic discharges. Discharges with relatively little energy might ignite hydrogen, which could be utilized as an AEA's energy source. The significantly limited heat transfer by convection at low air pressures at cruising altitudes is one of the constraints in designing MVDC power cables for an envisaged wide-body AEA. At an air pressure of 18.8 kPa, which is the air pressure at cruising altitude of wide-body aircraft, 12.2 km, the ampacity of a cable decreases. However, this considers only one pole of a bipolar cable in the duct, and as will be disclosed below, from the results for only one pole, the ampacity reduction for a bipolar cable cannot be estimated.

However, the effects of distance between poles and horizontal and vertical arrangement of poles regarding air pressure on the ampacity of bipolar MVDC power cable systems placed in a closed space for aircraft applications have not been investigated yet. Until now, all the work has been carried out on terrestrial cables or at atmospheric pressure.

As disclosed below, the ampacity flowing a 5 kV MVDC bipolar cable system placed in a closed space at different distances between poles for a reduced air pressure of 18.8 kPa is investigated by comparing the results with those obtained for a one-pole cable system in the duct, and it is shown that it is not possible to estimate the ampacity of a bipolar cable system from the results of one pole system. A coupled electrical, thermal, and computational fluid dynamics (CFD) FEM model of the bipolar cable system is developed in the COMSOL Multiphysics software to determine the ampacity flowing through the cables. Also, based on analytical and proven empirical correlations for conductive, radiative, and convective heat transfers at the steady state, an analytical model is developed to estimate the ampacity of the bipolar cable system at reduced pressures. The disclosed analytical model is applicable for atmospheric pressures and with proper modifications for systems with a larger number of poles. The results of the FEM and analytical models correlate at wide ranges of parameters such as ambient temperature, duct size, the distance between the negative and positive pole cables, and the overall diameter of the cable.

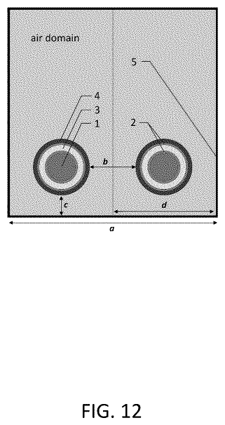

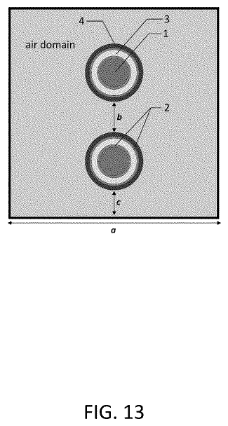

To examine the ampacity of the bipolar MVDC aircraft power cable operating at a pressure of 18.8 kPa in the COMSOL Multiphysics software, a coupled electrical, thermal, and CFD model is required. FIGS. 12-13 show a schematic of the geometry of the investigated cabling systems. Both the horizontal arrangement shown in FIG. 12 and the vertical arrangement shown in FIG. 13. The cables are placed at least at a 1 inch distance from the cable duct floor ‘c’ as shown in FIGS. 12-13. The detailed descriptions of the items in FIGS. 12-13 are presented in Tables VIII and IX.

TABLE VII

| Part | Description | Material | Value |
|---|---|---|---|
| 1 | Conductor | Copper | |
| 2 | Conductor and insulation screens | Semiconductor | |
| 3 | Insulation | NL-EPR | |
| 4 | Jacket | PVC | |
| 5 | Duct | Aluminum alloy | |
| a | Length of the duct side | | 1000 mm |
| b | Distance between the cables | | S |
| c | The minimum permissible distance | | 25.4 mm |
| | between the cables and the duct | | |
| d | Half of the duct's side | | 500 mm |

TABLE IX

| Parameters | Value |
|---|---|
| Conductor outer diameter (mm) | 25.4 |
| Conductor's screen outer diameter (mm) | 28.372 |
| Insulation outer diameter (mm) | 34.341 |
| Insulation's screen outer diameter (mm) | 35.856 |
| PVC jacket outer diameter (mm) | 40.44 |
| Rated temperature for normal operation (° C.) | 105 |

The disclosed model contains all heat transfer types. The heat transfer by natural convection is included by an air domain covering the whole duct. The air domain covers all the duct, so its boundaries which contact the duct, experience the ambient temperature. Although considering a constant ambient temperature for the duct simplifies the real condition of aircraft cables, assuming an air domain covering the whole duct with actual contact with the duct and without simplified inlet and outlet boundaries is a promising step towards having a more precise model. Nevertheless, the duct is made of aluminum with high thermal conductivity, and it may have contact with the ambient surface of the airplane. Regarding this high thermal conductivity and the nature of that disclosed, which is a steady-state type, after a long time, all parts of the duct experience a temperature equal to or very close to the temperature of the ambient surface of the airplane. Therefore, considering a uniform temperature equal to the ambient one for the duct is not an unrealistic assumption.

Also, to precisely model the heat transfer by radiation, the duct is assumed to be a 1-mm-thick aluminum. To disregard the computational errors in calculating the radiative heat transfer by the COMSOL Multiphysics software, the surface emissivity of the inner walls of the duct is assumed to be 1. The geometrical and thermal characteristics of the studied cable and its material are presented in Tables IX and X, respectively. The overall diameter of the cable, D₁, is 40.44 mm.

Only conductive heat transfer occurs between the cable's core conductor and its surface. The conductive heat transfer is given by the following equation:

$$ρ {C}_{p} \frac{\partial T}{\partial t} + ∇ \cdot ( - k ∇ T ) = Q - ∇ \cdot {q}_{0} \qquad ( 34 )$$

where k is the thermal conductivity (W (K m)⁻¹), T is the temperature (K), Cₚ is the specific heat capacity at the constant pressure (J (kg K)⁻¹), q₀ is the net outward radiative heat flux (W m⁻²), ρ is the density (kg m⁻³), and Q is the heat source (W m⁻³).

TABLE X

| | | NL- | | |
|---|---|---|---|---|
| Parameters | Copper | EPR | Semiconducting | PVC |
| Thermal | 400 | 0.3 | 10 | 0.19 |
| conductivity | | | | |
| (W (m K)⁻¹) | | | | |
| Heat capacity (J | 385 | 1800 | 2405 | 1050 |
| (kg K)⁻¹) | | | | |
| Density (kg m⁻³) | 8960 | 860 | 1055 | 1350 |
| Surface emissivity | — | — | — | 0.91 |

Since the heat losses in the insulation are negligible compared to losses in the conductor, Q is determined by the conductor losses.

The heat transfer in the air domain is in the form of natural heat convection. In the enclosing air domain, the heat equation is given by the following equation:

$$ρ {C}_{p} \frac{\partial T}{\partial t} + ρ {C}_{p} u \cdot ∇ T + ∇ \cdot ( - k ∇ T ) = Q + τ : ∇ u + \frac{- T}{ρ} \frac{\partial ρ}{\partial t} ( \frac{\partial P}{\partial t} + u \cdot ∇ P ) \qquad ( 35 )$$

where u is the air velocity vector (m s⁻¹), T is the temperature (K), Cₚ is the heat capacity at the constant pressure of the air (J (kg K)⁻¹), p is the air density (kg m⁻³), τ is the viscous tensor (Pa), P is the pressure (Pa), and k is the air's thermal conductivity of (W (K m)⁻¹). The operator ‘:’ stands for the double dot product, which denotes a tensor contraction as defined by: b=Σₙ Σₘ aₙₘ bₙₘ, is given by the following equation:

$$τ = μ ( ∇ u + {( ∇ u )}^{T} ) - \frac{2}{3} μ ( ∇ \cdot u ) {I}_{I} \qquad ( 36 )$$

where μ is the air's dynamic viscosity (kg (m s)⁻¹) and I_{I} is the identity matrix. The momentum equation and the equation of continuity will determine the velocity field given by the following equation:

$$ρ \frac{\partial u}{\partial t} + ρ ( u \cdot ∇ ) u = ∇ ( - {PI}_{I} + τ ) + ( ρ - {ρ}_{ref} ) g \qquad ( 37 )$$

$$\frac{\partial ρ}{\partial t} + ∇ \cdot ( ρu ) = 0 \qquad ( 38 )$$

where g is the acceleration of gravity (m s⁻²) and ρ_{ref} is the reference density (kg m⁻³). The air density, by considering it as an ideal gas, can be expressed as follows:

$$ρ = \frac{P}{R T} \qquad ( 39 )$$

where R is the universal gas constant, T is the temperature of the gas (K), and P is the pressure of the gas (Pa).

Considering P₁ is a point located on the outermost boundary of the cable and since the cable is in a cylindrical shape, the net outward radiative heat flux (q₀) at P₁ is given by the following equation:

$${q}_{o} = {ε}_{1} ( {E}_{b 1} ( T ) - {G}_{12} ) \qquad ( 40 )$$

where G₁₂ is the irradiance received at point P₁ from the ambient surface (W m⁻²), ε₁ is the emissivity of the cable surface, and E_{b1}(T) is the power radiated across all wavelengths (W m⁻²) from P₁ and is given by the following equation:

$${E}_{b 1} ( T ) = {n}^{2} {σ}_{S} {T}_{1}^{4} \qquad ( 41 )$$

where T₁ is the temperature of the point P₁ (K), σₛ is Stefan's constant (W m⁻²K⁻⁴, and n is the refractive index of air (n≈1). By considering an isothermal duct, G₁₂ can be expressed as follows:

$${G}_{12} = {F}_{12} [ {ϵ}_{2} {E}_{b 2} ( T ) + ( 1 - {ϵ}_{2} ) {G}_{21} ] \qquad ( 42 )$$

where G₂₁ is the irradiance received at any point of the duct from P₁ (W m⁻²), E_{b2}(T) is the power radiated from the duct (W m⁻²) and can be derived from equation (40) by replacing the temperature of the cable's surface with the ambient temperature, ε₂ is the emissivity of the duct, and F₁₂ is the view factor given by the following equation:

$${F}_{12} = {\int }_{A} \frac{cos {θ}_{1} cos {θ}_{2}}{π {R}^{2}} d A \qquad ( 43 )$$

where A is the surface area of the duct (m²), dA is the elemental area, R (m) is the line connecting any point on the duct to P₁ without crossing the cable, θ₁ is the polar angle formed by R with the surface normal of the cable, and θ₂ is the polar angles formed by R with the surface normal of the duct.

The electric, velocity, and temperature fields are coupled according to Equations (34-43). Based on the described expressions, the multi-physics FEM model of the horizontal and vertical arrangements is developed to determine the ampacity of the bipolar cable system at multiple conditions. The meshing parameters of the FEM model disclosed are as follows:
For the air domain, triangles with the maximum and minimum element sizes of 330 and 50 mm, respectively
For the poles, triangles with the maximum and minimum element sizes of 20 and 0.075 mm, respectively.
For the outermost boundaries of the poles, boundary meshing with the maximum and minimum size of 13 and 0.15 mm, respectively.
For the inner walls of the duct, two layers of rectangles with a stretching factor of 1.2 and thickness of 0.5 mm are included in the meshing
   The COMSOL study is time dependent with the simulation time of 30 h to reach the steady state condition.

To obtain the ampacity of the bipolar cable system at the steady state, an analytical model can be developed based on analytical and proven empirical correlations governing radiative and convective heat transfers. The steady-state conductive heat transfer in the cable can be expressed as follows:

$$\frac{{T}_{c o r e} - {T}_{s}}{{Σ}_{i = 1}^{n} {R}_{i}} = Q \qquad ( 44 )$$

where T_{core} is the conductor temperature (K), T_{S} is the cable surface temperature, Rᵢ is the thermal resistance (K W⁻¹) of the ith layer of the cable, and Q is the conductive heat transfer (W m⁻¹). Since the heat losses in the insulation are negligible compared to losses in the conductor, Q is determined by the conductor losses, so it can be obtained using the following equation:

$${Q}_{c o n} = {I}^{2} {R}_{d c} \qquad ( 45 )$$

where R_{dc} is the conductor's resistance (Ω) and I is the cable's current (A). The conductor's resistance is a function of its temperature as given in the following linear resistivity (ρₑ) expression:

$${p}_{e} = {p}_{0} ( 1 + α ( {T}_{c} - {T}_{ref} ) ) \qquad ( 46 )$$

where T_{C} is the conductor temperature (K), ρ₀ is the electric resistivity (Ω m) at the reference temperature, T_{ref} is the reference temperature (K), and α is the resistivity temperature coefficient (K⁻¹). The thermal resistances (Rᵢ) is given by the following equation:

$${R}_{i} = \frac{ln ( \frac{{r}_{2 i}}{{r}_{1 i}} )}{2 π {k}_{i}} \qquad ( 47 )$$

where kᵢ is the thermal conductivity of the ith layer (W K⁻¹ m⁻¹), r₂ᵢ and r₁ᵢ are outer and inner radii of the ith layer (m), respectively. The net outward radiative heat transfer from the surface for an object i with a uniform surface temperature can be obtained by the following equation:

$${Q}_{r} = {\sum }_{j = 1}^{n} \frac{{J}_{i} - {J}_{j}}{{( {A}_{i} {F}_{i j} )}^{- 1}} \qquad ( 48 )$$

where N is the total number of the objects that exchange radiative heat with the object i, Aᵢ is the surface area (m²) of the object i, and Fᵢⱼ is the view factor of object j to the object i. Also Jᵢ and Jⱼ are the radiosity of objects i and j, respectively, and can be obtained by solving N equations stated as follows:

$$\frac{{E}_{bi} - {J}_{i}}{( 1 - {e}_{i} ) {( {e}_{i} {A}_{i} )}^{- 1}} = {{\sum }_{j = 1}}^{n} \frac{{J}_{i} - {J}_{j}}{{( {A}_{i} {F}_{ij} )}^{- 1}} \qquad ( 49 )$$

where E_{bi} can be calculated for each object using equation (8) and εᵢ is the surface emissivity of the object i. The view factor of the second cable of the bipolar cable system and the duct to the first cable can be, respectively, expressed as follows:

$${F}_{12} = \frac{1}{2 π} [ π + {[ {( \frac{2 + s}{r} )}^{2} - 4 ]}^{\frac{1}{2}} - ( \frac{2 + s}{r} ) - 2 {cos}^{- 1} [ \frac{2 r}{2 + s} ] ] \qquad ( 50 )$$

$${F}_{13} = 1 - {F}_{12} \qquad ( 51 )$$

where r is the outer radius of the cable and S is the distance between the cables. The convective heat transfer for a horizontal cylinder is given by the following equation:

$${Q}_{c} = π k ( {T}_{3} - {T}_{S} ) {( 0.6 + \frac{0.387 {Ra}_{D}^{\frac{1}{6}}}{{( 1 + {( \frac{0.599}{Pr} )}^{\frac{9}{16}} )}^{\frac{8}{27}}} )}^{2} \qquad ( 52 )$$

where k is thermal conductivity (W (Km)⁻¹) of the air, T₃ is the ambient temperature, and Ra_{D} and Pr are Reynolds and Prandtl numbers that are, respectively, given by the following equation:

$${Ra}_{D} = \frac{g {ρ}^{2} {C}_{p} {a}_{p} ( {T}_{S} - {T}_{ext} ) {D}_{ch}^{3}}{k μ} \qquad ( 53 )$$

$$Pr = \frac{μ {C}_{p}}{k} \qquad ( 54 )$$

where D_{ch} is the cable characteristic diameter (m) and usually equals to the diameter of the cable (D), μ is the air's dynamic viscosity (Pa s), Cₚ is the heat capacity of the air (J (kg K)⁻¹), g is the acceleration of the gravity (ms⁻²), p is the air density (kg m⁻²), and αₚ is the coefficient of thermal expansion (K⁻¹). The material data are evaluated at the average of T₃ and T_{S} except for the air density which is calculated at T_{S}. The convective heat flux of a horizontal cylinder can be calculated from equations (53)-(55) if the Reynolds number is less than 10¹². For the studied cable diameter, pressure, and temperature, the Reynolds number is always lower than the mentioned criteria. Also, the total heat losses at the core conductor should be equal to the radiative and convective heat transfers, and can be written as follows:

$$Q = {Q}_{r} + {Q}_{c} \qquad ( 55 )$$

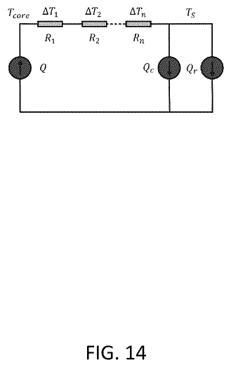

Using equations (44)-(55), the thermal equivalent circuit of a cable in the bipolar cable system at the steady state is shown in FIG. 14.

Obtaining the ampacity of the bipolar cable system requires an iterative method since the surface temperature of the cable can be calculated by knowing the current of the bipolar cable system. However, the radiative and convective heat transfers for the bipolar cable system are different from calculations based on equations (48) and (51), since the cables' surface temperature is not uniform and for the small distance between the cables, the convective heat transfer is a coupled function of both cables. Therefore, as disclosed, wo modifications are disclosed to estimate the radiative and convective heat transfers of the bipolar cable system. The cable's surface area, Aᵢ, in equation (48) can be modified as follows:

$${A}_{m} = {A}_{i} ( 1 - {k}_{r} exp ( \frac{- S}{2 {rT}_{r}} ) ) \qquad ( 56 )$$

where kᵣ and Tᵣ are radiative coefficients. The physical interpretation of the modified surface area for radiative heat transfer is that the effective surface area for radiation is reduced due to the non-uniformity of the surface temperature when the poles are in a very close vicinity. As the distance between the poles increases, the modified surface area becomes closer to the actual surface area. For the horizontal configuration, the characteristic diameter of the cable, D_{ch}, in equation (53) for S≤0.4D can be modified as follows:

$${D}_{mh} = D ( {k}_{ch 1} - {k}_{ch 2} ( \frac{S}{2 r} - 0.4 ) ) \qquad ( 57 )$$

for 0.4D≤S≤0.8D can be expressed as follows:

$${D}_{mh} = D ( {k}_{ch 3} - {k}_{ch 4} ( \frac{S}{2 r} - 0.8 ) ) \qquad ( 58 )$$

and for 0.8D≤S≤7D is given by the following equation:

$${D}_{mh} = D ( {k}_{ch5} - {k}_{ch 6} exp ( \frac{- ( \frac{S}{2 r} - 0.8 )}{{T}_{ch}} ) ) \qquad ( 59 )$$

where kch1, kch2, kch3, kch4, kch5, kch6, and Tch are convective coefficients for the horizontal configuration. Also, for the vertical configuration, the characteristic diameter of the cable, D_{ch}, for S≤0.3 D can be modified as follows:

$${D}_{mv} = {k}_{cv 1} D \qquad ( 60 )$$

for 0.3D≤S≤2D can be expressed as follows:

$${D}_{mv} = D ( {k}_{cv 2} + {k}_{cv 3} ( \frac{S}{2 r} - 0.3 ) ) \qquad ( 61 )$$

and for 2D≤S is given by the following equation:

$${D}_{mv} = D ( {k}_{cv 4} - {k}_{cv 5} exp ( \frac{- ( \frac{S}{2 r} - 2 )}{{T}_{cv}} ) ) \qquad ( 62 )$$

where k_{cv1}, k_{cv2}, k_{cv3}, k_{cv4}, k_{cv5}, and T_{cv} are convective coefficients for the vertical configuration. To explain the modified characteristic diameter, it could be argued that as the distance between the poles is small, the effective diameter of the poles is smaller than actual diameter of the poles for calculating convective heat transfer by empirical correlations, which are originally defined for a long horizontal cylinder. By increasing the distance between the poles, the modified diameter becomes closer to the actual diameter of the poles, as the convective heat transfer is decoupled for large distances between the poles. Table XI presents the disclosed radiative and convective coefficients. It is worth mentioning that the disclosed model for the horizontal configuration is valid for the maximum distance of 7D between the poles, while for the vertical configuration, the model is valid for all distances between the poles.

TABLE XI

| Coefficient | Value |
|---|---|
| kᵣ | 0.00325 |
| Tᵣ | 0.15 |
| kch₁ | 0.885 |
| kch₂ | 1.0925 |
| kch₃ | 0.848 |
| kch₄ | 0.0925 |
| kch₅ | 1.498 |
| kch₆ | 0.65 |
| T_{ch} | 2.5 |
| kcv₁ | 0.4335 |
| kcv₂ | 0.4335 |
| kcv₃ | 0.236 |
| kcv₄ | 1.06 |
| kcv₅ | 0.2253 |
| Tcv | 0.5 |

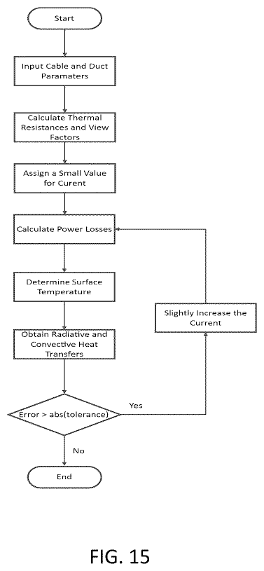

These coefficients are tuned using the data of the FEM model at an ambient temperature of 40° C. and an ambient pressure of 18.8 kPa when the duct size is 1000 mm. FIG. 15 shows the flowchart of how the ampacity of the bipolar cable system is calculated in the disclosed analytical model. The error can be defined as follows:

$$error = Q - {Q}_{r} - {Q}_{c} \qquad ( 63 )$$

and the tolerance shown in the flowchart of FIG. 15 can be assumed as 5×10⁻². The disclosed model that is presented in the flowchart of FIG. 15 can be summarized as follows:
For a desired cable that is used as poles, its geometrical and thermal characteristics are used as inputs of the model.
By using inputs, the thermal resistance and view factors are calculated using equations (47), (50), and (51).
By assigning a small value for the current, the heat losses in the core conductor of the poles are calculated using equations (45) and (46).
By using equation (44), the surface temperature is calculated, and radiative and convective heat transfers are calculated by equations (48), (49), (52-54), and (56-62).
Error is calculated using equation (63). If it is smaller than 5×10⁻², the assigned current is the ampacity. However, if the error is larger than 5×10⁻², then the current must be increased slightly and all steps from ‘Calculate Power Losses’ must be repeated.

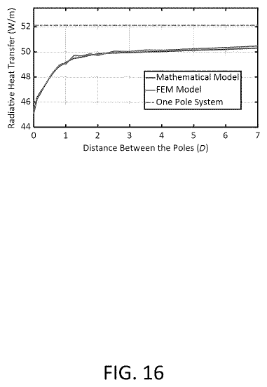

FIGS. 16-19 show the calculated radiative and convective heat transfer by the FEM and the disclosed analytical models when the ampacity of the cable is obtained using the FEM model at different distances between the poles as a factor of the overall diameter of the poles which equals the overall diameter of the presented cable above, D=D₁. The results are for the bipolar cable system placed in a 1000 mm duct, a=1000 mm in FIGS. 12 and 13, with ambient temperature and pressure of 40° C. and 18.8 kPa, respectively. The radiative heat transfer for each pole of the bipolar cable system calculated by the disclosed analytical model correlates greatly with the radiative heat transfer obtained by the FEM model with a maximum difference between the disclosed and FEM models of 0.46% and 1.05%, respectively, for horizontal and vertical configurations.

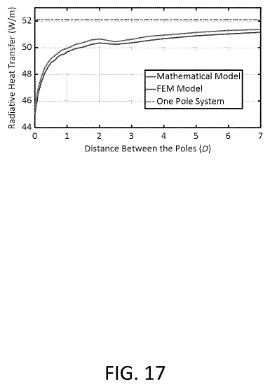

As seen in FIGS. 16-17, for both horizontal and vertical configurations, by increasing the distance between the poles, for each pole of the bipolar cable system, the radiative heat transfer increases, as the view factor of the poles to each other decreases, which can be concluded from equation (51). However, it cannot reach the value of one cable system and its growth tends to decrease by increasing the distance.

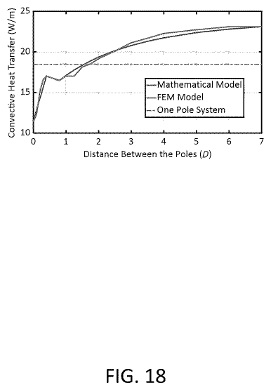

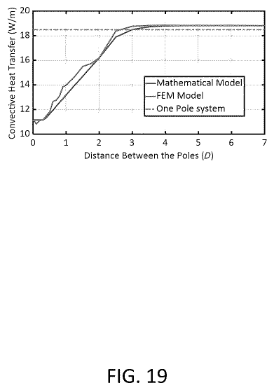

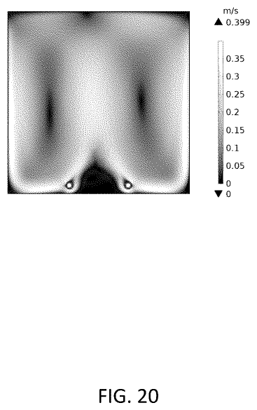

The convective heat transfer for each pole of the bipolar cable system calculated by the disclosed analytical model correlates greatly with the radiative heat transfer obtained by the FEM model with a maximum difference between the disclosed and FEM models of 0.46% and 1.05%, respectively, for horizontal and vertical configurations. Contrary to the radiative heat transfer, for each pole of the bipolar cable system, the convective heat transfer exceeds the value of one pole system as shown in FIGS. 18-19. However, its growth is not linear and tends to decrease with increasing distance. The convective heat transfer reaches its maximum amount at a smaller distance, 4D, for the vertical configuration compared to the horizontal one, 6D. The reason that the bipolar cable system shows a higher convective heat transfer at large distances between the poles compared to the one cable system is shown in FIGS. 20-22.

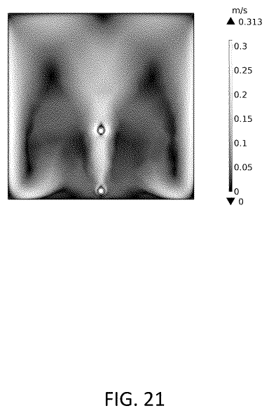

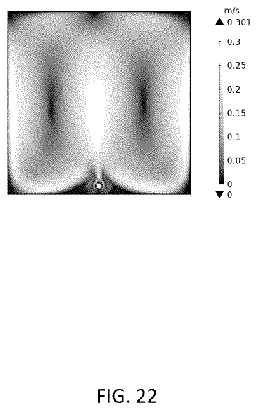

As seen in FIGS. 20-21, the bipolar cable system experiences a velocity field where for the horizontal configuration, poles experience airflow with the maximum velocity of the air or are enclosed by a larger velocity field compared to the one-pole system for the vertical configuration. However, as shown in FIG. 22, the one cable system is surrounded by a velocity field with a very low velocity of air; therefore, its convective heat transfer is limited compared to the bipolar system, as can be concluded from equation (35).

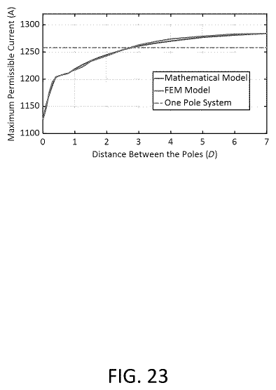

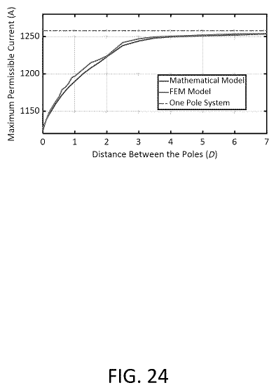

A comparison between the calculated ampacity of the bipolar cable system using the FEM and analytical model is shown in FIGS. 23-24 for horizontal and vertical configurations, respectively. As seen in FIG. 23, the calculated ampacity calculated by the disclosed analytical model correlates greatly with the FEM model with a maximum difference of −0.52% and 0.75% for the horizontal and vertical configurations, respectively.

The increased convective heat transfer for each pole of the horizontal bipolar cable system at large distances yields higher ampacity for large distances between the poles compared to one pole system with a maximum of 2% larger at 7D. However, the growth in ampacity of the horizontal configuration tends to decrease by increasing the distance between the poles, following the trends of radiative and convective heat transfers for the horizontal configuration.

It is worth mentioning that despite a larger difference in calculated convective heat transfer by the analytical model for distances smaller than 0.4D, the calculated ampacity by the disclosed model is in a very close range with the FEM model since the convective heat transfer for small distance constitutes a smaller share of total heat transfer.

As disclosed, the ampacity of a bipolar MVDC power cable system designed for aviation applications at the reduced pressure of cruising altitude of wide-body aircraft has been investigated. To obtain the ampacity of the bipolar cable systems, a precise FEM model containing all possible types of heat transfer such as conductive, convective, and radiative coupled with electrical and CFD physics was developed in the COMSOL Multiphysics software. Also, based on analytical and proven empirical correlations governing conductive, radiative, and convective heat transfers, an analytical model is disclosed that can precisely calculate ampacity of the bipolar cable system for the horizontal and vertical configurations. The model uses modified coefficients for radiative and convective heat transfers to cope with the analytical and proven empirical correlations with the non-isothermal bipolar cable system. The disclosed model, follows an algorithm to calculate the ampacity of the bipolar cable system. The geometrical and thermal characteristics of a chosen cable as poles are used as inputs of the algorithm, and then, the ampacity of the bipolar cable system for a desired distance between the poles is calculated. The results of the FEM and analytical models are as follows:
The radiative heat transfer for each pole of the bipolar cable system always remains lower than that of one pole system; however, the convective heat transfer for each pole of the bipolar cable system exceeds its value of one pole system when the distance between the cables reaches a specific amount.
For the horizontal bipolar cable system configuration, for each pole of the bipolar cable system, the growth in the convective heat transfer compensates for the reduction of radiative one, so compared to the one pole system, resulting in a larger ampacity for large distances; however, for the vertical bipolar cable system configuration, for each pole of the bipolar cable system, the reduction in the radiative heat transfer is larger than the excessive convective heat transfer, so the ampacity always remains lower than that of one pole system.

The disclosed model is valid for a wide range of temperatures, distance between the cables, duct size, and overall cable diameter, making it a useful tool for designing bipolar cable systems for aviation applications. However, the disclosed model can be further improved by incorporating the duct size in calculating the convective heat transfer and adding terms related to the minimum permissible distance between the poles and the duct.

A cuboid bipolar geometry cable is disclosed with a multilayer insulation system, and its performance analyzed under low-pressure conditions. Also, using coaxial cable systems may result in a reduction in the overall size, volume, and weight of the aircraft's EPSs in bipolar MVDC systems. Compared to a conventional bipolar MVDC power cable, a coaxial bipolar cable system experiences a larger surface area, thus the radiative and convective heat transfers will increase. For operating in low-pressure situations, the development of a ±5 kV coaxial bipolar MVDC power cable without active cooling techniques has not yet been developed. The effectiveness of a coaxial geometry is disclosed and compared with cuboid and conventional cylindrical bipolar cable systems.

A coupled electrical, thermal, and computational fluid dynamics (CFD) model developed by using COMSOL Multiphysics for designing and analyzing the optimal bipolar cable system for envisaged wide-body AEA is disclosed. Different types of bipolar cable systems such as conventional cylindrical, cuboid (square), and coaxial have been developed while all three geometries benefit from a multilayer insulation system. A comparative study has been conducted among those designs of cable to determine the best combination of bipolar cable systems for use in future widebody AEA.

To achieve a high-power-density and low-system-mass EPS for aircraft applications, the cables must be designed to either show a larger maximum permissible current at the same cross-sectional area and mass, or for a given ampacity, show a smaller cross-sectional area and mass. Considering the second approach, to design cables to achieve a high-power-density and low-system-mass EPS, thermal analysis is necessary. The total heat loss at the core conductor of a cable is equal to the radiative and convective heat transfers, as can be written as:

$$Q = {Q}_{r} + {Q}_{C} \qquad ( 63 )$$

where Q is the total heat loss of the core conductor (W·m⁻³), Qᵣ is the radiative heat transfer (W·m⁻³), and Q_{c} is the convective heat transfer (W·m⁻³). By decreasing the cross-sectional area and mass of the cables for a given ampacity, Q will increase since the resistivity of the core conductor will be increased by decreasing the cross-sectional area. Therefore, the radiative and convective heat transfers must be increased to compensate for that growth in the total heat loss.

The radiative heat transfer from the surface of an object i with a uniform surface temperature can be obtained by:

$${Q}_{ri} = {{\sum }_{j = 1}}^{N} \frac{{J}_{i} - {J}_{j}}{{( {A}_{i} {F}_{ij} )}^{- 1}} \qquad ( 64 )$$

where N is the total number of the objects that exchange radiative heat with the object i, Aᵢ is the surface area (m²) of the object i, and Fᵢⱼ is the view factor of object j to the object i. Also, Jᵢ and Jᵢ are the radiosity of objects i and j, respectively, and can be obtained by solving N equations as:

$$\frac{{E}_{bi} - {J}_{i}}{( 1 - {ϵ}_{i} ) {( {ϵ}_{i} {A}_{i} )}^{- 1}} = {{\sum }_{j = 1}}^{N} \frac{{J}_{i} - {J}_{j}}{{( {A}_{i} {F}_{ij} )}^{- 1}} \qquad ( 65 )$$

where εᵢ is the surface emissivity of the object i, and E_{bi} can be calculated for each object as:

$${E}_{bi} ( T ) = {n}^{2} {σ}_{S} {T}_{i}^{4} \qquad ( 66 )$$

where Tᵢ is the surface temperature of the object i (K), σs is Stefan's constant (W·m⁻²K⁻⁴), and n is the refractive index of air (n≈1).

For the cylindrical and cuboid (square) bipolar cable systems, the view factor of the poles to each other, F₁₂, and the duct to the poles, F₁₃, can be respectively expressed as:

$${F}_{12} = {\int }_{A} \frac{cos {θ}_{1} cos {θ}_{2}}{π {R}^{2}} dA \qquad ( 67 )$$

$${F}_{13} = 1 - {F}_{12} \qquad ( 68 )$$

where R (m) is the line connecting any point on the surface of the poles to each other without crossing the poles, θ₁ and θ₂ are polar angles formed by R with the surface normal of the poles, respectively, A₁ is the surface area of the pole (m²), and dA₁ is the elemental area.

For the coaxial bipolar cable system, F₁₂ equals to 0, since only one object, the coaxial cable, interacts with the duct. Also, to further simplify Eq. (63) by assuming that the poles have an equal radiosity, J₁=J₂, and using equations (66) and (68), the radiative heat transfer of the poles can be obtained as:

$${Q}_{{r}_{1}} = {Q}_{{r}_{2}} = \frac{{A}_{1} {σ}_{S} ( {T}_{1}^{4} - {T}_{3}^{4} )}{\frac{1 - {ϵ}_{1}}{{ϵ}_{1}} + \frac{1}{1 - {F}_{12}} + \frac{2 ( 1 - {ϵ}_{3} )}{{ϵ}_{3} ( \frac{{A}_{3}}{{A}_{1}} )}} \qquad ( 69 )$$

and the total radiative heat transfer is given by

$${Q}_{r} = {Q}_{{r}_{1}} + {Q}_{{r}_{2}} \qquad ( 70 )$$

Equation (69) shows that as the surface area of the poles increases, the radiative heat transfer increases if the increase in the surface area exceeds the increase in the view factor between the poles, F₁₂. For a given distance between the poles, by increasing the surface area of the poles, F₁₂ increases for both cylindrical and cuboid (square) configurations. For a given cross-sectional area, the surface area, A₁, and the view factor of poles to each other, F₁₂, at the distances of 0 and 2 inches between the poles when the overall diameter of the cylindrical cable is 1 inch are compared for the cuboid shape to the cylindrical one, yielding:

$${A}_{{1}_{cuboid}} = ( \frac{2}{\sqrt{π}} ) {A}_{{1}_{cylindrical}} \qquad ( 71 )$$

At 0 inch distance:

$${F}_{{12}_{cuboid}} \approx ( 1.375 ) {F}_{{12}_{cylindrical}} \qquad ( 72 )$$

At 2 inch distance:

$${F}_{{12}_{cuboid}} \approx ( 0.9875 ) {F}_{{12}_{cylindrical}} \qquad ( 73 )$$

The results show that by changing the shape of the cable from cylindrical to cuboid (square) form, although the surface area increases by approximately a factor of 2/\sqrt{π}=1.13, the view factor also increases for small distances between the poles, however, by increasing the distance between the poles, its value is less than that of cylindrical one, leading to further enhancing the radiative heat transfer. Nevertheless, according to equations (71) and (72), the radiative heat transfer of a cuboid (square) bipolar cable system at small distances may be smaller than that of a cylindrical one, so a careful selection of material with a certain range of emissivity for the duct and cables and optimizing the size of the cables and the duct is necessary to minimize this effect. It can be concluded from equations (71) and (73) that for large distances, to have an equal radiative heat transfer as the cylindrical poles, the surface area, thus cross-sectional area and mass, of the cuboid poles in a bipolar cable system can be reduced.

For the coaxial bipolar cable system, the radiative heat transfer can be expressed as:

$${Q}_{{r}_{1}} = {Q}_{{r}_{2}} = \frac{{A}_{1} {σ}_{S} ( {T}_{1}^{4} - {T}_{3}^{4} )}{\frac{1 - {ϵ}_{1}}{{ϵ}_{1}} + \frac{1}{{F}_{13}} + \frac{2 ( 1 - {ϵ}_{3} )}{{ϵ}_{3} ( \frac{{A}_{3}}{{A}_{1}} )}} \qquad ( 74 )$$

where F₁₃=1. Therefore, for the coaxial cable system, with a cable's surface temperature equal to that of a cylindrical one, the radiative heat transfer increases. However, it is worth mentioning that the total radiative heat transfer for the coaxial cable is given by:

$${Q}_{r} = {Q}_{{r}_{coaxial}} \qquad ( 75 )$$

meaning that to have an equal radiative heat transfer for a coaxial bipolar cable system and a cylindrical bipolar cable system with sufficient distance between the poles, the surface area should be approximately 2 times of each pole. This results in a coaxial bipolar cable system with a cross-sectional area and mass of approximately 2 times that of a cylindrical bipolar cable system. However, by having an inner hollow conductor, the surface area and radiative heat transfer will increase without significantly increasing the mass of the coaxial cable, so the coaxial bipolar cable system with a hollow inner conductor can be considered as a solution to reduce the mass of the aircraft cable.

The convective heat transfer for a cylindrical shape cable can be empirically expressed as:

$${Q}_{c} = π k ( {T}_{3} - {T}_{S} ) {( 0.6 + \frac{0.387 {Ra}_{D}^{\frac{1}{6}}}{{( 1 + {( \frac{0.599}{Pr} )}^{\frac{9}{16}} )}^{\frac{8}{27}}} )}^{2} \qquad ( 76 )$$

where k is thermal conductivity (W.(K.m)⁻¹) of the air, Ra_{D} and Pr are Reynold and Prandtl numbers that are respectively given by:

$${Ra}_{D} = \frac{g {ρ}^{2} {C}_{p} {a}_{p} ( {T}_{S} - {T}_{ext} ) {D}_{ch}^{3}}{k μ} \qquad ( 77 )$$

$$Pr = \frac{μ {C}_{p}}{k} \qquad ( 78 )$$

where D_{ch} is the cable's characteristic diameter (m) and usually equals to the diameter of the cable, μ is the dynamic viscosity of the fluid (Pa·s), Cₚ is the heat capacity of the air (J.(kg.K)⁻¹), g is the acceleration of the gravity (m·s⁻²), p is the air density (kg·m⁻²), and αₚ is the coefficient of thermal expansion (K⁻¹). The material data are evaluated at the average of T₃ and T₁ except for the air density which is calculated at T₁.

For a cuboid shape cable, the governing equation of convective heat transfer is not as straight as equation (76), therefore, a comparison between the convective heat transfers is not possible by using these empirical expressions. Nevertheless, the coaxial bipolar cable system has the same cylindrical shape as the cylindrical bipolar cable system, so it can be concluded from equations. (76)-(78) where the convective heat transfer of the coaxial bipolar cable system is larger. Equation (76) is for one pole of the cylindrical bipolar cable system, so for the coaxial cable system to have the same convective heat transfer, the overall diameter of the coaxial cable system needs to be increased by approximately 2 times of each pole. Therefore, same as the issue for the radiative heat transfer, the cross-sectional and mass of the coaxial bipolar cable system will be 2 times of that of the cylindrical bipolar cable system. A coaxial bipolar cable system with a hollow inner conductor can be a solution to increase the convective heat transfer without increasing the mass.

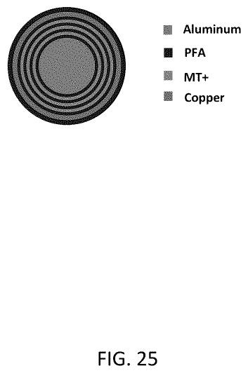

Although equations (63)-(76) give an insight into analyzing designing parameters that influence the radiative and convective heat transfers, they are mostly based on assumptions for a specific condition. Therefore, using equations (63)-(76) yields approximate results for comparing bipolar cable systems for all case studies. To accurately examine the electrical and thermal performance of several types of aircraft bipolar MVDC power cables operating at 18.8 kPa, which is the air pressure at a usual cruising height, 12.2 km from sea level, of wide-body aircraft, a comprehensive coupled electrical, thermal, and CFD model is developed by using COMSOL Multiphysics. The model includes laminar flow, surface-to-surface heat radiation, magnetic fields, electric currents, and heat transfer modules. All forms of heat transfer, namely conduction, convection, and radiation, are considered for modeling. FIG. 25 shows the configuration of one of the poles where the ARC-SC-T-MMEI design was used in the cylindrical bipolar cable system. The same structure was used for the cuboid (square) bipolar cable system. This design shows the best performance in terms of overcoming the challenges associated with aircraft power cables operating under different environmental conditions. In this cable design, both polyamides (PI) and fluoropolymer polymers are considered for the insulation system, resulting in an optimal design for preventing arcing and arc tracking while meeting higher breakdown voltages. The ARC-SC-T-MMEI has a Teflon® PFA (0.5-mil) layer and a Kapton® MT+ (1.5-mil) layer wrapped in 6.5-mil film for a higher breakdown voltage in the inner part of the insulation.

Between the wrapped layers and the outermost layer of the insulation, there is a 5 mil-thick copper screen layer. The outer layer of this design contains a 4 mils thick Teflon® PFA jacket. Table XII represents the properties of the materials used in the bipolar cable systems.

TABLE XII

| | Teflon ® | Kapton ® | Aluminum | |
|---|---|---|---|---|
| Parameters | PFA | MT+ | 1350 | Copper |
| Thermal Conductivity | 0.195 | 0.75 | 238 | 400 |
| (W · (m · K)⁻¹) | | | | |
| Dielectric Constant | 2 | 4.2 | — | — |
| Density (Kg · m⁻³) | 2150 | 1420 | 2705 | 8960 |
| Dielectric Strength | 256 × | 208.5 × | — | — |
| (V · m⁻¹) | 10⁶ | 10⁶ | | |

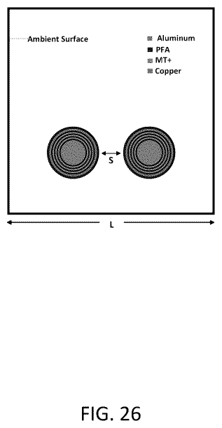

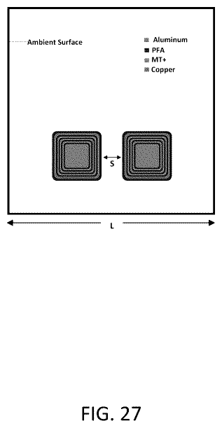

FIGS. 26-27 show the 2D geometry of the conventional cylindrical bipolar cable system and cuboid (square) bipolar cable system, respectively, considered for modeling and simulations. For both bipolar cable systems, both poles benefit from the ARC-SC-T-MMEI configuration as the insulation. The duct, depicted in FIGS. 26-27 as the ambient surface, encloses the bipolar cable system to model heat radiation. The duct is a square-shaped domain with a thickness of 1 mm. The size of the duct's side (L) is 1000 mm. The outer surface of the duct maintains the same temperature of 40° C., while the inner walls of the duct meet air at a pressure of 18.8 kPa, representing the conditions encountered at the cruising altitude of a wide-body aircraft. In FIGS. 26-27, the distance between the negative and positive poles is referred to as “S”. The distance “S” is varied for finding the optimal design of bipolar cables to use in future wide-body aircraft. Also, a sufficient distance must be maintained between the cable and the duct sides to ensure that the cable's breakdown will not endanger the safety of the plane or its systems. For this purpose, the poles are positioned 1 inch above the duct floor for all the simulations used in this study. For cuboid (square) geometry rounded corners were employed to mitigate the infinite electric field intensity due to sharp edges.

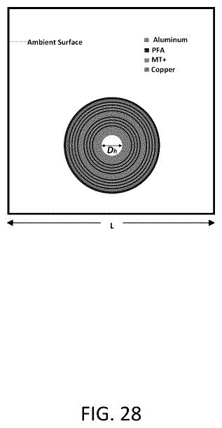

The 2D geometry considered for modeling and simulations disclosed of the coaxial bipolar cable system without a hollow inner conductor and the coaxial bipolar cable system with a hollow inner conductor are shown in FIG. 28. For the coaxial bipolar cable system without a hollow inner conductor, the diameter of the hollow area, Dₕ, equals to 0. For both coaxial bipolar cable systems, the surface area of the inner and outer conductors is considered the same. For the insulation between inner and outer conductors/poles, the same 6.5-milthick-wrapped inner insulation part is used. For the outer insulation, the same insulation layers as the cylindrical and cuboid (square) cables are used. For both coaxial bipolar cable systems, the inner conductor/pole voltage is +5 kV, and the outer conductor/pole voltage is −5 kV. For having the same cross-sectional area for the inner and outer conductors of both coaxial bipolar cable systems, the following formula is used:

$${r}_{con 1}^{2} - {r}_{h}^{2} = {r}_{con 3}^{2} - {r}_{con 2}^{2} \qquad ( 79 )$$

where rₕ is the radius of the hollow part, r_{con1} is the radius of the outer part of the inner conductor, r_{con2} is the radius of the inner part of the outer conductor and r_{con3} is the radius of the outer part of the outer conductor. For the coaxial bipolar cable system without a hollow inner conductor, rₕ equals to 0.

The heat equation in the core conductor of the cable to its surface can be expressed as:

$$ρ {C}_{p} \frac{\partial T}{\partial t} + ∇ \cdot ( - k ∇ T ) = Q + {q}_{0} \qquad ( 80 )$$

where ρ is the density (kg·m⁻³), Cₚ is the specific heat capacity at the constant pressure (J.(kg.K)⁻¹), k is thermal conductivity (W.(K.m)⁻¹), T is the temperature (K), and q₀ is the net outward radiative heat flux (W·m⁻³). Q is the heat source (W·m⁻³) resulting from Joules heating loss and can be described as:

$$Q = {I}^{2} R \qquad ( 81 )$$

where I is the conductor current (A) and R is the conductor resistance (Ω). Considering P₁ is a point located on the surface of the cable, the net outward radiative heat flux (q₀) at P₁ is given by:

$${q}_{o} = {ε}_{1} ( {E}_{b 1} ( T ) - {G}_{12} ) \qquad ( 82 )$$

where ε₁ is the emissivity of the cable surface, G₁₂ is the irradiation received at point P₁ from the ambient surface (W·m⁻²), and E_{b1}(T) is the power radiated across all wavelengths (W·m⁻²) from P₁. The heat equation in the air domain can be described as:

$$ρ {C}_{p} \frac{\partial T}{\partial t} + ρ {C}_{p} u \cdot ∇ T + ∇ \cdot ( - k ∇ T ) = Q + τ : ∇ u + \frac{- T}{ρ} \frac{\partial ρ}{\partial t} ( \frac{\partial P}{\partial t} + u \cdot ∇ P ) \qquad ( 83 )$$

where ρ is the air density (kg·m⁻³), Cₚ is the heat capacity at the constant pressure of the air (J.(kg.K)⁻¹), u is the air velocity vector (m·s⁻¹), k is the thermal conductivity of the air (W.(K.m)⁻¹), T is the temperature (K), τ is the viscous tensor (Pa), q is the heat flux (W·m⁻³) and P is the pressure (Pa). The operator “:” stands for the double dot product. The fluid (here air) velocity field can be determined from the momentum equation and the equation of continuity that are respectively expressed as:

$$ρ \frac{\partial u}{\partial t} + ρ ( u \cdot ∇ ) u = ∇ \cdot ( - {PI}_{l} + τ ) + ( ρ - {ρ}_{r e f} ) g \qquad ( 84 )$$

$$\frac{\partial ρ}{\partial t} + ∇ \cdot ( ρ u ) = 0 \qquad ( 85 )$$

where ρ_{ref} is the reference density (kg·m⁻³), and g is the acceleration of gravity (m·s⁻²). The distribution of the electric field can be calculated using:

$$E = - ∇ V \qquad ( 86 )$$

$${J}_{e} = σ E \qquad ( 87 )$$

where Jₑ is the current density (A·m⁻²), V is the voltage (V), and σ is the conductivity (S·m⁻¹). In addition, the steady-state space charge density can be determined using:

$$σ E \cdot ∇ ( \frac{{ϵ}_{e}}{σ} ) = {ρ}_{e} \qquad ( 88 )$$

where ρₑ is the space charge density, and εₑ is the permittivity. The conductivity of polymeric DC cables can be calculated using the empirical expression of.

$$σ ( E , T ) = {σ}_{0} {e}^{( \frac{- a}{T} + b E )} \qquad ( 89 )$$

where E is the electric field (V·m⁻¹), a is the coefficient of temperature, b is the coefficient of electric field, and σ₀ is a constant associated with polymeric material. Equations (80)-(89) demonstrate the coupling between the velocity field, temperature field, and electric field. The study period is determined to be 30 hours to reach the steady case. To compare the bipolar cable system, a parameter of J can be defined as:

$$J = m \cdot A \qquad ( 90 )$$

where m is the total cable's mass per unit length (kg·m⁻¹) and A is the overall cross-sectional area of the bipolar cable system (m²), which for the coaxial bipolar cable system with an inner hollow conductor contains the hollow area too. Designs with smaller J are preferred because they allow for higher power densities and reduced overall system masses.

This disclosure identifies a high-power-density and low-system-mass bipolar MVDC power cable system for wide-body AEA. Special high-temperature conductors, 1350-O aluminum wires with 63% IACS, having a maximum permissible temperature of 260° C. are used for the core. For all bipolar cable systems, the overall diameter of the poles' core conductors is obtained to reach the maximum permissible temperature of 260° C. when the current is 1000 A, the voltage of the poles is +5 kV and −5 kV, the duct's temperature is 40° C., and the air pressure is 18.8 kPa. All bipolar cable systems are optimized and analyzed via the coupled model disclosed above.

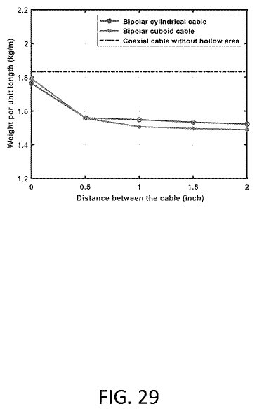

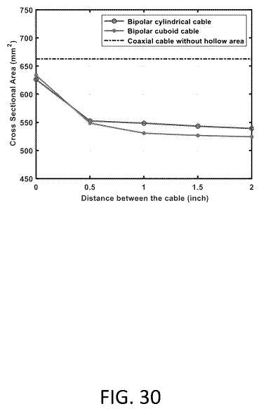

FIGS. 29-30 compare the weight per unit length and cross-sectional area of the cylindrical bipolar cable system, cuboid bipolar cable system, and coaxial bipolar cable system without a hollow inner conductor.

As shown in FIGS. 29-30, for both cylindrical and cuboid designs, at 0 inches between the cables, both weight per unit length and cross-sectional area are higher than larger distances. Also, the lowest weight per unit length and cross-sectional area for both cylindrical bipolar cable system and cuboid bipolar cable system occur when the distance between the poles is 2 inches.

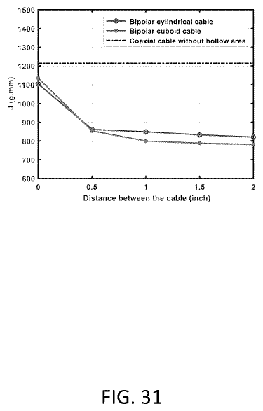

In FIG. 31, J of three types of bipolar cable systems are shown. Changing in the J follows the same trend as its constituting elements, larger at S=0 inches than S=2 inches, for both cylindrical bipolar cable system and cuboid bipolar cable system. Also, except at S=0, J of the cuboid bipolar cable system is smaller than that of the cylindrical one at S=0.5, 1, 1.5, and 2 inches where the difference in the J is larger at larger distances. At S=0 inches, J of the cuboid bipolar cable system is 1135.57, which is 2.82% higher than the cylindrical one and 6.53% lower than the coaxial bipolar cable system. Also, at S=2 inches, J of the cuboid bipolar cable system is 781.60, which is 4.82% and 35.67% lower than the cylindrical bipolar cable system and coaxial cable system, respectively.

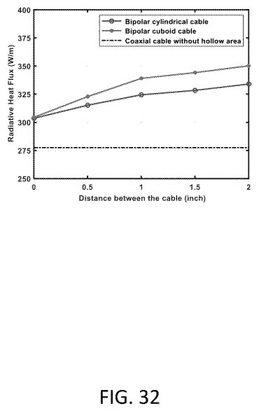

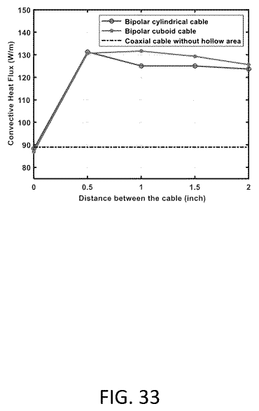

Weight per unit length, cross-sectional area, and J of the cylindrical bipolar and cuboid cable systems drastically reduce when the distance between the cable increases from 0 inches to 2 inches. However, by further increasing the distance between the cables, the reduction rates tend to decrease slowly. To understand these trends and further analyze the affecting parameters, the radiative and convective heat fluxes of the cylindrical bipolar cable system, cuboid bipolar cable system, and coaxial bipolar cable system without a hollow inner conductor are evaluated in FIGS. 32-33.

The radiative heat flux of both cylindrical bipolar cable system and cuboid bipolar cable system increases by increasing the distance between the poles; however, the growth is significantly higher for the cuboid-shaped cables than for the cylindrical-shaped cables, since the changes in the view factor of the poles to each other for the cuboid bipolar cable system is larger for than that of the cylindrical bipolar cable system, as can be concluded from equations (72) and (73). Although the radiative heat transfer of the cylindrical cable system is almost similar to the cuboid one at S=0, for larger distances, the radiative heat transfer of the cuboid bipolar cable system is larger. This is despite the fact that the rate of cross-sectional area of the cylindrical bipolar cable system to the cuboid bipolar cable system increases by increasing the distance. This is because the varying view factor of the poles to each other on the radiative heat transfer for the cuboid bipolar cable system compensates for the deceased surface area rate, causing a larger radiative heat transfer for the cuboid bipolar cable system at larger distances.

FIG. 33 shows the convective heat flux. As the radiative heat flux, for S-0, the convective heat fluxes are much lower than larger distances for the cylindrical bipolar cable system and cuboid bipolar cable system. The lowest convective heat transfer is for the cuboid bipolar cable system at S=0, however, that for the cylindrical bipolar cable system is not much larger, since the lack of convection on one side drastically reduces convective heat transfer for both bipolar cable systems. The maximum convective heat transfer for the cuboid bipolar cable system occurs at S=1 inches, then it decreases by increasing the distance. For the cylindrical bipolar cable system, the maximum convective heat transfer occurs at a distance of 0.5 inches. By increasing the distance between the poles from 0 inches, the convective heat transfer sharply increases for both bipolar cable systems, since at larger distances, all sides of the cables are available for convective heat transfer. However, by further increasing the distance between the poles, since the surface area decreases, the convective heat transfer reduces for both bipolar cable systems.

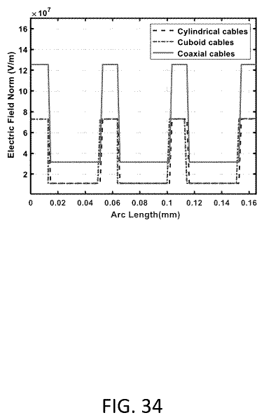

Although the sum of radiative and convective heat fluxes for the cuboid bipolar cable system at S=0 inches is almost similar to the cylindrical one, by increasing the distance between the poles it is larger for the cuboid system, since the cross-sectional area of the cuboid bipolar cable system and thus cross-sectional of its conductor, is smaller than its cylindrical counterpart, as shown in FIG. 30. A smaller cross-sectional area of the conductor results in higher resistance per unit length, hence larger heat losses for a given current. Since the sum of the radiative and convective heat transfers must be equivalent to the heat losses, its value for the cuboid bipolar cable system is larger than the cylindrical one. Tables XIII, XIV, and XV present the data of optimally designed cylindrical, cuboid, and coaxial bipolar cable systems, respectively. Also, in FIG. 34, the electric field norm across the insulation of the bipolar cable systems is shown. Since the insulation thickness and potential difference across the insulation of the cylindrical and cuboid bipolar cable systems are the same, the electric field norm is the same. However, the potential difference across the insulation of the coaxial cable system is increased compared to other bipolar cable systems, from 5 kV to 10 kV, so the electric field norm across its insulation increases. Nevertheless, all bipolar cable systems are electrically safe to operate.

TABLE XIII

| | | | Cross- | Weight | |
|---|---|---|---|---|---|
| | | | sectional | per unit | |
| Distance | Core | | area | length | |
| between | Conductor | Cable | (mm²) | (kg · m⁻¹) | J |
| | 19.18 | 19.97 | 626.25 | 1.7636 | 1104.46 |
| 0.5 | 17.97 | 18.76 | 552.65 | 1.5602 | 862.25 |
| 1 | 17.90 | 18.69 | 548.53 | 1.5488 | 849.56 |
| 1.5 | 17.81 | 18.60 | 543.26 | 1.5342 | 833.47 |
| 2 | 17.74 | 18.53 | 539.18 | 1.5320 | 821.17 |

TABLE XIV

| | Core | | Cross | | |
|---|---|---|---|---|---|
| Distance | Conductor | Cable | sectional | Weight | |
| between | side | side | arca of the | per unit | |
| the cables | length | length | cable | length | J |
| (inch) | (mm) | (mm) | (mm²) | (kg · m⁻¹) | (g · mm) |
| 0 | 17.10 | 17.89 | 633.58 | 1.7923 | 1135.57 |
| 0.5 | 15.86 | 16.65 | 548.62 | 1.5569 | 854.15 |
| 1 | 15.59 | 16.37 | 530.86 | 1.5076 | 800.32 |
| 1.5 | 15.52 | 16.31 | 526.83 | 1.4965 | 788.40 |
| 2 | 15.49 | 16.28 | 524.53 | 1.4901 | 781.60 |

TABLE XV

| Parameters | Value |
|---|---|
| Inner Conductor Diameter (mm) | 19.82 |
| Insulation Between Inner and Outer Conductor | 20.15 |
| Overall Diameter (mm) | |
| Outer Conductor Diameter (mm) | 28.264 |
| Cable's Overall Diameter (mm) | 29.052 |
| Cross Sectional Area of the Cable (mm²) | 662.86 |
| Weight Per Unit Length of the cable (kg · m⁻¹) | 1.8329 |
| J (g · mm) | 1214.956 |

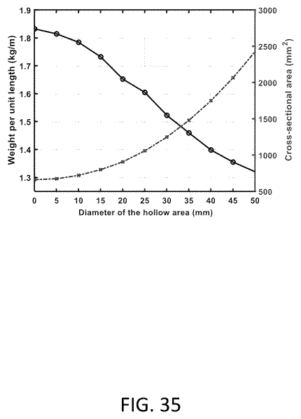

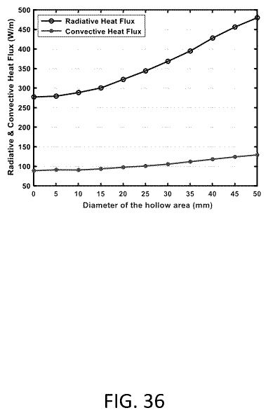

For the coaxial bipolar cable system with a hollow inner conductor, the voltage of the inner conductor is +5 kV and the outer one is −5 kV. Although the weight per unit length of the cable decreased by increasing the diameter of the hollow area, growth in the cross-sectional area is significantly larger, so J is crucially larger for those larger distances, as can be concluded from FIG. 35. For the coaxial bipolar cable system with a hollow inner conductor, there is a trade-off between the weight per unit length of the cable and the cross-sectional area. If the cross-sectional area of the cable is not a vital part of designing the aircraft cable, the coaxial bipolar cable system with a hollow inner conductor can be considered as a solution for providing high-power-density, low-system-mass aircraft cable. For example, when the diameter of the hollow area is 50 mm, the weight per unit length of the coaxial bipolar cable system is about 1.3206 kg·m⁻¹, which is lower than the cuboid bipolar cable systems at a distance of 2 inches. Also, the radiative and convective heat fluxes of the designed cable with different diameters of the hollow area are shown in FIG. 36. Both radiative and convective heat fluxes increase by increasing the diameter of the hollow area, as can be concluded from equations (74)-(78). When the diameter of the hollow area is 50 mm, the radiative heat transfer is around 485 W/m, which is 74.46% higher than no hollow area in the inner conductor, 278 W/m. In the case of convective heat transfer, the growth is not so much like radiative heat transfer, but it follows the same trend. For a 50 mm hollow area in the inner conductor, the convective heat flux is about 130 W/m, which is about 46% higher than no hollow area.

As disclosed, bipolar MVDC power cable systems that are required for high-power-density and low-system-mass envisaged wide-body AEA's electric power systems are designed and analyzed. Three different types of bipolar cable systems such as cylindrical bipolar cable system, cuboid bipolar cable system, and coaxial bipolar cable system are considered. For the insulation of the cables, optimally designed ARC-SC-TMMEI multilayer insulation systems are used, which resolve challenges of aviation cables, including arc and arc tracking, PD, and thermal management. The designed cable systems are thermally and electrically analyzed using a coupled electric, thermal, and fluid flow dynamic model. The model accounted for all possible heat transfer ways, including conduction, convection, and radiation. To evaluate the disclosed cable systems, J is introduced, which is the product of the overall weight per unit of the cables and the cross-sectional area of the cables. Among all designs, the cuboid bipolar cable system with a 2-inch distance between the poles experiences the lowest J. Also, for all distances between the poles, the cuboid bipolar cable system outperformed the cylindrical one in terms of J, except at 0 inches distance between the poles. If only the weight per unit length is considered, the coaxial bipolar cable with a hollow conductor can also be considered a viable option for future wide-body all-electric aircraft. Also, the electric field norm across the insulation of the bipolar cable systems is analyzed, and it was shown that all designed bipolar cable systems are electrically safe.

At the cruising altitude of wide-body aircraft (12.2 km), the low air pressure of 18.8 kPa limits convective heat transfer. As a result, the maximum permissible current flowing through the cable decreases compared to atmospheric pressure. Additionally, the use of bipolar cable systems further restricts the maximum permissible current. So, the optimal design of bipolar cable systems is crucial for achieving a high-power density and low-system-mass electrical power system (EPS) in cable aircraft applications. Increasing the radiative and convective heat transfer of the cables is one possible solution for increasing the current-carrying capacity of the cables. While an increase in surface area will result in a faster rate of radiative heat transfer, increases in convective heat transfer may be significant, minor, or even nonexistent, depending on a variety of factors, such as the shape of the cable. Cuboid (square) and rectangular cables can be utilized as a solution to make up for the decrease in the maximum permitted current at decreased pressures by increasing the outer surface area of the cable system while maintaining the same mass and cross-sectional area. To address the theoretically infinite electric field at sharp edges, it is essential to incorporate rounded corners in the design of cuboid and rectangular cables.

Disclosed is a design of a rectangular bipolar geometry cable with a multilayer insulation system and compares its weight and dimensions to cylindrical, cuboid, and coaxial alternatives in low-pressure conditions. For application in low-pressure situations, a rectangular bipolar MVDC power cable system with a voltage of ±5 kV has not yet been developed. A comprehensive finite element model (FEM) model integrating electrical, thermal, and computational fluid dynamics (CFD) is disclosed to design and evaluate the most efficient bipolar cable system for a future wide-body AEA. Various bipolar cable systems, including conventional cylindrical, cuboid, rectangular, and coaxial designed with multilayer insulation systems and optimized to achieve a maximum allowable temperature of 260° C. under a current of 1000 A and pole voltages of +5 kV and −5 kV, respectively. A comparative study was conducted among those designs to determine the optimal combination of bipolar cable systems for future wide-body AEA applications.

For aircraft applications, to develop an efficient EPS that exhibits high power density and low system mass, the cables need to be designed to either support a higher maximum current with the same cross-sectional area and mass or have a smaller cross-sectional area and mass while maintaining the same ampacity. As disclosed, a second approach is considered for designing the MVDC bipolar cables. In the second approach, thermal analysis is required while designing cables to accomplish a high-power-density and low-system-mass EPS. A cable's total heat loss at its core conductor can be expressed as the sum of its radiative and convective heat transfers:

$$Q = {Q}_{r} + {Q}_{c} \qquad ( 91 )$$

where Q is the core conductor's total heat loss (W·m⁻³), Q_{c} is the convective heat transfer (W·m⁻³), and Qᵣ is the radiative heat transfer (W·m⁻³). For a given ampacity, decreasing the mass and cross-sectional area of the cables will increase Q. This is because decreasing the cross-sectional area increases the resistivity of the core conductor. Hence, it is necessary to improve the radiative and convective heat transfers to make up for the increase in total heat loss.

The radiative heat transfer from the object's surface which has a uniform temperature, can be determined by:

$${Q}_{r i} = {\sum }_{j = 1}^{N} \frac{{J}_{i} - {J}_{j}}{{( {A}_{i} {F}_{i j} )}^{- 1}} \qquad ( 92 )$$

where N represents the total number of objects that share radiative heat with the object i, Aᵢ represents the surface area (m²) of the object i, and Fᵢⱼ represents the view factor of object j relative to the object i. Additionally, Jᵢ and Jⱼ represent the radiosities of objects i and j, respectively, and can be determined by solving a system of N equations:

$$\frac{{E}_{b i} ( T ) - {J}_{i}}{( 1 - {ϵ}_{i} ) {( {ϵ}_{i} {A}_{i} )}^{- 1}} = {\sum }_{j = 1}^{N} \frac{{J}_{i} - {J}_{j}}{{( {A}_{i} {F}_{i j} )}^{- 1}} \qquad ( 93 )$$

where εᵢ represents the surface emissivity of the object i, and E_{bi} can be calculated for each object as:

$${E}_{b i} ( T ) = {n}^{2} {σ}_{S} {T}_{i}^{4} \qquad ( 94 )$$

where n is the refractive index of air (n≈1), Tᵢ is the i object's surface temperature (K), and σₛ is the Stefan's constant (W·m⁻²K⁻⁴).

For the cylindrical, rectangular, and cuboid bipolar cable systems, the view factor of the positive and negative poles to each other, F₁₂, and the duct to the poles, F₁₃, can be stated as:

$${F}_{12} = {\int }_{A} \frac{cos {θ}_{1} cos {θ}_{2}}{π {R}^{2}} dA \qquad ( 95 )$$

$${F}_{13} = 1 - {F}_{12} \qquad ( 96 )$$

where A₁ is the surface area (m²) of the poles, R (m) is the line that connects any two points on the surface of the poles without crossing them, θ₁ and θ₂ are the polar angles that R forms with the pole surface normals, respectively, and dA₁ is the elemental area.

Since the coaxial cable interacts only with the duct in the coaxial bipolar cable system, F₁₂ equals to zero. By assuming that the poles have an equal radiosity, J₁=J₂, and utilizing equations (94) and (96), one may further reduce equation (91) and obtain the radiative heat transfer of the poles as:

$${Q}_{{r}_{1}} = {Q}_{{r}_{2}} = \frac{{A}_{1} {σ}_{S} ( {T}_{1}^{4} - {T}_{3}^{4} )}{\frac{1 - {ϵ}_{1}}{{ϵ}_{1}} + \frac{1}{1 - {F}_{12}} + \frac{2 ( 1 - {ϵ}_{3} )}{{ϵ}_{3} ( \frac{{A}_{3}}{{A}_{1}} )}} \qquad ( 97 )$$

and the formula for the total radiative heat transfer is,

$${Q}_{r} = {Q}_{{r}_{1}} + {Q}_{{r}_{2}} \qquad ( 98 )$$

Radiative heat transfer rises with increasing surface area of the poles, as shown by equation (97), provided that this increase is greater than the increase in the view factor between the poles, F₁₂. Increasing the surface area of cylindrical, rectangular, and cuboid configurations results in an increase in F₁₂ for a given distance between the poles. When the overall diameter of the cylindrical cable is 1 inch, the outer surface area, A₁, of cuboid and rectangular cables with a given cross-sectional area is compared to the cylindrical one, resulting in:

$${A}_{{1}_{c u b o i d}} = ( \frac{2}{\sqrt{π}} ) {A}_{{1}_{cylindrical}} \qquad ( 99 )$$

$${A}_{{1}_{r e c t a n g u l a r}} = ( \frac{6}{\sqrt{5 π}} ) {A}_{{1}_{c y l i n d r i c a l}} \qquad ( 100 )$$

In Table XVI, the ratio of the view factor of poles to each other, F₁₂, at the distances of 0 to 2 inches between the poles are shown. As can be seen from equations (99) and (100), the surface area of the cable rises by roughly a factor of 1.13 and 1.51, when the shape is changed from cylindrical to cuboid and cylindrical to rectangular, respectively.

TABLE XVI

| Distance between the | F_{12cuboid}/ | F_{12rectangular}/ |
|---|---|---|
| poles | F_{12cylindrical}^{a} | F_{12cylindrical}^{a} |
| 0 | 1.3760 | 0.4587 |
| 0.5 | 1.3189 | 0.2622 |
| 1 | 1.1654 | 0.1955 |
| 1.5 | 1.0586 | 0.1677 |
| 2 | 0.9878 | 0.1527 |

^{a}View factors are calculated for, without rounding the edges of the cuboid and rectangular cables.

However, from Table XVI, it can be shown that the view factor also increases for small distances between the poles, however, by increasing the distance between the poles, its value decreases, leading to further enhancing the radiative heat transfer. Furthermore, rectangular shapes consistently exhibit a ratio of less than 1, indicating a more favorable radiation effect. Nevertheless, radiative heat transfer of a cuboid bipolar cable system at small distances may be lower than that of a cylindrical one; thus, it is important to select a material with a certain range of emissivity for the duct and cables and to optimize the size of the cables and the duct to reduce this effect.

The radiative heat transfer for the coaxial bipolar cable system is represented as:

$${Q}_{{r}_{1}} = {Q}_{{r}_{2}} = \frac{{A}_{1} {σ}_{S} ( {T}_{1}^{4} - {T}_{3}^{4} )}{\frac{1 - {ϵ}_{1}}{{ϵ}_{1}} + \frac{1}{{F}_{13}} + \frac{2 ( 1 - {ϵ}_{3} )}{{ϵ}_{3} ( \frac{{A}_{3}}{{A}_{1}} )}} \qquad ( 101 )$$

where F₁₃=1. With the surface temperature of the cable being the same as that of a cylindrical cable, the radiative heat transfer in the coaxial cable system improves. The entire radiative heat transfer for the coaxial wire, however, is calculated as:

$${Q}_{r} = {Q}_{{r}_{coaxial}} \qquad ( 102 )$$

meaning that to provide an amount of radiative heat transfer equal to a cylindrical bipolar cable system, the surface area of a coaxial bipolar cable system should be roughly double that of each pole for a cylindrical one. Radiative heat transfer is enhanced in square and rectangular cables due to their larger outer surface area compared to cylindrical cables. While square or rectangular cables may face limitations in bend radii depending on orientation, cylindrical cables generally offer greater flexibility, allowing uniform bending in all directions. Square and rectangular cables can sometimes be packed more densely than round ones, taking up less space when used in certain applications. This is especially useful in small spaces or situations where space utilization is critical.

The convective heat transfer for a cylindrical cable can be empirically expressed as:

$${Q}_{c} = π k ( {T}_{1} - {T}_{3} ) {( 0.6 + \frac{0.387 {Ra}_{D}^{\frac{1}{6}}}{{( 1 + {( \frac{0.599}{Pr} )}^{\frac{9}{16}} )}^{\frac{8}{27}}} )}^{2} \qquad ( 103 )$$

where k is thermal conductivity (W.(K.m)⁻¹) of the air, Ra_{D} and Pr are Reynold and Prandtl numbers that are respectively given by:

$${Ra}_{D} = \frac{g {ρ}^{2} {C}_{p} {a}_{p} ( {T}_{S} - {T}_{ext} ) {D}_{ch}^{3}}{k μ} \qquad ( 104 )$$

$$Pr = \frac{μ {C}_{p}}{k} \qquad ( 105 )$$

where D_{ch} is the cable's characteristic diameter (m) and usually equals to the diameter of the cable, μ is the dynamic viscosity of the fluid (Pa·s), Cₚ is the heat capacity of the air (J.(kg.K)⁻¹), g is the acceleration of the gravity (m·s⁻²), p is the air density (kg·m⁻²), and αₚ is the coefficient of thermal expansion (K⁻¹). The material data are evaluated at the average of T₃ and T₁ except for the air density which is calculated at T₁.

For a cuboid and rectangular shape cable, the governing equation of convective heat transfer is not as straight as in equation (103), therefore, a comparison between the convective heat transfers is not possible by using these empirical expressions. Nevertheless, the coaxial bipolar cable system has the same cylindrical shape as the cylindrical bipolar cable system, so it can be concluded from equations (103)-(105) that the convective heat transfer of the coaxial bipolar cable system is larger.

Equation (103) is for one pole of the cylindrical bipolar cable system, so for the coaxial cable system to have the same convective heat transfer, the overall diameter of the coaxial cable system needs to be increased by approximately 2 times each pole. Therefore, same as the issue for the radiative heat transfer, the cross-sectional and mass of the coaxial bipolar cable system will be 2 times that of the cylindrical bipolar cable system.

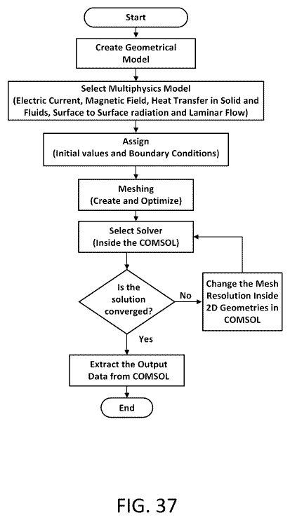

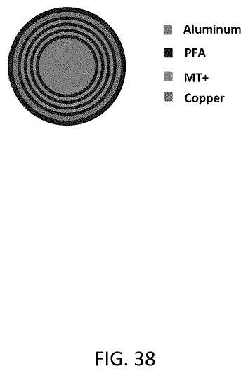

Equations (91)-(103) provide insight into the analysis of design parameters that affect radiative and convective heat transfers. However, it is important to note that these equations are primarily based on specific assumptions for a given condition. Therefore, for all case studies, employing equations (91)-(103) offers approximative findings for comparing bipolar cable systems. To assess the electrical and thermal performance of various types of bipolar MVDC power cables used in wide-body aircraft at a typical cruising altitude of 12.2 km above sea level, an integrated model combining electrical, thermal, and CFD is developed in COMSOL Multiphysics. The model incorporates laminar flow, magnetic fields, heat transfer modules, surface-to-surface heat radiation, and electric currents modules. The modeling process considers all three forms of heat transfer: conduction, convection, and radiation. FIG. 37 describes the flowchart of the modeling procedure and FIG. 38 depicts the configuration of the multilayer insulation system considered for cables. This insulation system is used for rectangular, cuboid, and conventional bipolar cable systems as disclosed. This design demonstrates superior performance in addressing the challenges associated with aircraft power cables operating in diverse environmental conditions. This cable design incorporates both polyamides (PI) and fluoropolymer polymers in the insulation system to achieve an optimal design that effectively prevents arcing and arc tracking, while also meeting higher breakdown voltage requirements. It consists of a Teflon® PFA layer (0.5-mil) and a Kapton® MT+ layer (1.5-mil) enclosed in a 6.5-mil film. This design enhances the breakdown voltage within the inner portion of the insulation. The insulation also consists of a 5 mil-thick copper screen layer located between the wrapped layers and the outermost layer. The outermost layer is 4 mils thick Teflon® PFA jacket. Table XVII represents the characteristics of the materials used in the different shapes of bipolar cable systems.

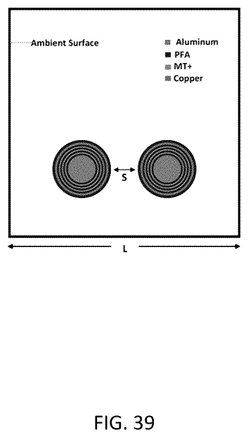

FIGS. 39-42 show the 2D geometries of the four types of bipolar cable systems that are utilized for modeling and simulations in this study. The multilayer insulation configuration is utilized for the main insulating system of both poles of cylindrical, cuboid, and rectangular bipolar cable systems. To simulate heat radiation, the bipolar cable system is enclosed in the duct, which is shown as the ambient surface in FIGS. 39-42. The duct is a 1 mm thick square-shaped domain. The duct's side (L) measures 1 m in length. The duct's outside surface remains at a constant temperature of 40° C., and the pressure inside the duct is 18.8 kPa, representing the conditions encountered at the cruising altitude of a widebody aircraft. The “S” in FIGS. 39-42 represents the separation between the negative and positive poles. Bipolar cables for future wide-body airplanes are optimally designed regarding “S”. Additionally, a sufficient gap must be kept between the cable and the duct sides to guarantee that the failure of the cable won't jeopardize the safety of the aircraft or its systems. For all the simulations utilized in this work, the poles are placed 1 inch above the duct floor. Rounded corners were utilized in cuboid (square) and rectangular geometry to reduce the infinite electric field intensity caused by sharp edges

TABLE XVII

| | Teflon ® | Kapton ® | Aluminum | |
|---|---|---|---|---|
| Parameters | PFA | MT+ | 1350 | Copper |
| Thermal Conductivity | 0.195 | 0.75 | 238 | 400 |
| (W · (m · K)⁻¹) | | | | |
| Dielectric Constant | 2 | 4.2 | — | — |
| Density (Kg · m⁻³) | 2150 | 1420 | 2705 | 8960 |
| Dielectric Strength | 256 × | 208.5 × | — | — |
| (V · m⁻¹) | 10⁶ | 10⁶ | | |

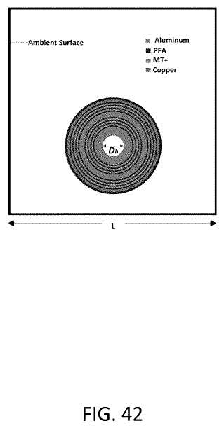

In FIG. 42, the 2D geometry of the coaxial bipolar cable system is shown. In coaxial bipolar cable systems, the cross-sectional area of the inner and outer conductors is assumed to be equal. The same 6.5-mil-thick-wrapped insulation configuration is utilized for the insulation between inner and outer conductors/poles. For the outer insulation, the same insulation layers as cylindrical cables are used. The inner conductor/pole voltage is +5 kV, while the outer conductor/pole voltage is −5 kV. For having the same cross-sectional area for the inner and outer conductors of coaxial bipolar cable systems the following formula is used.

$${r}_{con 1}^{2} - {r}_{h}^{2} = {r}_{con 3}^{2} - {r}_{con 2}^{2} \qquad ( 106 )$$

where r_{con1} is the radius of the outer part of the inner conductor, r_{con2} is the radius of the inner part of the outer conductor and r_{con3} is the radius of the outer part of the outer conductor. The heat equation from the cable's core conductor to its outside can be written as:

$$ρ {C}_{p} \frac{\partial T}{\partial t} + ∇ \cdot ( - k ∇ T ) = Q + {q}_{0} \qquad ( 107 )$$

where ρ is the density (kg·m⁻³), k is thermal conductivity (W.(K.m)⁻¹), Cₚ is the specific heat capacity at the constant pressure (J.(kg.K)⁻¹), T is the temperature (K), and q₀ is the net outward radiative heat flux (W·m⁻³). Q is the amount of heat (W·m⁻³) that comes from joules heat loss. It can be written as:

$$Q = {I}^{2} R \qquad ( 108 )$$

where I represents conductor current (A) and R represents the resistance (Ω).

Considering P₁ is a point located on the surface of the cable, the net outward radiative heat flux (q₀) at P₁ is expressed by:

$${q}_{o} = {ε}_{1} ( {E}_{b 1} ( T ) - {G}_{12} ) \qquad ( 109 )$$

where ε₁ is the emissivity of the cable surface, G₁₂ is the irradiation received at point P₁ from the ambient surface (W·m⁻²), and E_{b1}(T) is the power radiated across all wavelengths (W·m⁻²) from P₁. The heat equation in the air domain can be described as:

$$ρ {C}_{p} \frac{\partial T}{\partial t} + ρ {C}_{p} u \cdot ∇ T + ∇ \cdot ( - k ∇ T ) = Q + τ : ∇ u + \frac{- T}{ρ} \frac{\partial ρ}{\partial t} ( \frac{\partial P}{\partial t} + u \cdot ∇ P ) \qquad ( 110 )$$

where ρ is the density of the air (kg·m⁻³), Cₚ is the heat capacity at the constant pressure (J.(kg.K)⁻¹), u is the air velocity vector (m·s⁻¹), k is the thermal conductivity of the air (W.(K.m)⁻¹), T is the temperature (K), τ is the viscous tensor (Pa), q is the heat flux (W·m⁻³) and P is the pressure (Pa). The operator “:” stands for the double dot product. The fluid (here air) velocity field:

$$ρ \frac{\partial u}{\partial t} + ρ ( u \cdot ∇ ) u = ∇ \cdot ( - {PI}_{I} + τ ) + ( ρ - {ρ}_{ref} ) g \qquad ( 111 )$$

$$\frac{\partial ρ}{\partial t} + ∇ \cdot ( ρ u ) = 0 \qquad ( 112 )$$

where ρ_{ref} is the reference density (kg·m⁻³), and g is the acceleration of gravity (m·s⁻²).

The distribution of the electric field can be calculated using:

$$E = - ∇ V \qquad ( 113 )$$

$${J}_{e} = σ E \qquad ( 114 )$$

where Jₑ is the current density (A·m⁻²), Vis the voltage (V), and σ is the conductivity (S·m⁻¹). In addition, the steady-state space charge density can be determined using:

$$σ E \cdot ∇ ( \frac{{ϵ}_{e}}{σ} ) = {ρ}_{e} \qquad ( 115 )$$

where ρₑ is the space charge density, and εₑ is the permittivity.

The conductivity of polymeric DC cables can be calculated using the empirical expression of:

$$σ ( E , T ) = {σ}_{0} {e}^{( \frac{- a}{T} + bE )} \qquad ( 116 )$$

where E is the electric field (V·m⁻¹), a is the coefficient of temperature, b is the coefficient of electric field, and σ₀ is a constant associated with the polymeric material. The Electric Current module in COMSOL Multiphysics software calculates the electric field across the insulation by solving the electrical conductivity expression. This solution includes both the current and Poisson's electric fields. Hence, the electric field present in the cables is considered as the overall electric field. The electric conductivity of Teflon® PFA and Kapton® MT+ is not available, so the electric conductivity of ETFE and P₁ is used as a substitute for these materials, respectively. Table XVIII presents the parameters of P₁ and ETFE.

TABLE XVIII

| Parameters | σ₀ (S/m) | a (K) | b (mm/kV) |
|---|---|---|---|
| PI | 1.677e−9 | 3319 | 0.05558 |
| ETFE | 2.027e−10 | 4061 | 0.03097 |

Equations (107)-(116) demonstrate the coupling between the temperature field, velocity field, and electric field. To mitigate the risk of system failure and breakdown, the insulation system for the MVDC cable system was designed based on the following criteria:

$$\begin{matrix}{E}_{max ( i )} < 0.8 {E}_{bd ( i )} & i = 1 : n\end{matrix} \qquad ( 117 )$$

where Eₘₐₓ₍ᵢ₎ and E_{bd(i)} are the maximum electric field and breakdown strength of i-th dielectric layer, respectively, and n is the number of dielectric layers. To compare the bipolar cable system, a parameter of J can be defined as:

$$J = m \cdot A \qquad ( 118 )$$

where A is the overall cross-sectional area of the bipolar cable system (m²), and m is the total cable's mass per unit length (kg·m⁻¹). Designs with a smaller J are preferred because they allow for higher power densities and lower total system masses. The computational complexity of a FEM simulation in COMSOL Multiphysics can vary depending on several factors, including the specific physics modules involved, the mesh size, the solver settings, boundary conditions and the complexity of the geometry. For reaching the steady state, the simulation time is considered 30 hours in this model.

Table XIX represents the data for conventional cylindrical MVDC bipolar cable systems. The data presents the distance between the cables, core conductor's minimum diameter to maintain the maximum permissible temperature of 260° C., minimum diameter of the cables, surface area of the cables, weight per unit length of the cables, and J of the cable systems disclosed above. The studied geometry is depicted in FIG. 39.

TABLE XIX

| | | | Cross- | | |
|---|---|---|---|---|---|
| Distance | Core | | sectional | Weight | |
| between | conductor | Cable | area of | per unit | |
| the poles | diameter | diameter | the cable | length | J |
| (inch) | (mm) | (mm) | (mm²) | (kg · m⁻¹) | (g · mm) |
| 0 | 19.18 | 19.967 | 626.25 | 1.7636 | 1104.46 |
| 0.5 | 17.97 | 18.757 | 552.65 | 1.5602 | 862.25 |
| 1 | 17.90 | 18.687 | 548.53 | 1.5488 | 849.56 |
| 1.5 | 17.81 | 18.597 | 543.26 | 1.5342 | 833.47 |
| 2 | 17.74 | 18.527 | 539.18 | 1.5320 | 821.17 |

From the chart, it can be shown that by increasing the distance between the cables, S, the core conductor diameter reduces. As a result, the cables' overall diameter as well as the surface area also decreases. Minimum J is found for S=2 inches distance between the cables, 821.17 g·mm, which is about 25% lower than the J found for S=0 inches distance, when the value is 1104.46 g·mm.

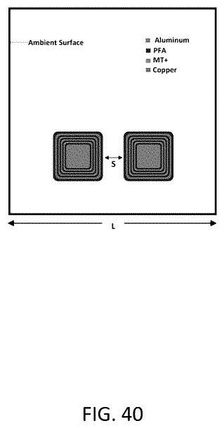

Table XX presents the data for cuboid bipolar MVDC cable systems. The data presents the distance between the cables, core conductor's one side length, overall cables one side length, surface area of the cable, weight per unit length of the cable, and J of the cable systems as disclosed above. The studied geometry is depicted in FIG. 40.

TABLE XX

| | | | Cross- | | |
|---|---|---|---|---|---|
| Distance | Core | | sectional | Weight | |
| between | conductor | Cable | area of | per unit | |
| the poles | diameter | diameter | the cable | length | J |
| (inch) | (mm) | (mm) | (mm²) | (kg · m⁻¹) | (g · mm) |
| 0 | 17.10 | 17.89 | 633.58 | 1.7923 | 1135.57 |
| 0.5 | 15.86 | 16.65 | 548.62 | 1.5569 | 854.15 |
| 1 | 15.59 | 16.37 | 530.86 | 1.5076 | 800.32 |
| 1.5 | 15.52 | 16.31 | 526.83 | 1.4965 | 788.40 |
| 2 | 15.49 | 16.28 | 524.53 | 1.4901 | 781.60 |

As it can be seen from the data, the lowest weight per unit length, thus the lowest J for cuboid bipolar cable systems is found for S=2 inches distance. The overall cross-sectional area also decreases when the distance between the cables increases. Therefore, the minimum J is found for S=2 inches distance between the cables, 781.60 g·mm, which is about 31% lower than the J found for S=0 inches distance.

TABLE XXI

| Parameters | Value |
|---|---|
| Diameter of the inner conductor (mm) | 19.82 |
| Diameter over insulation between inner and outer | 20.15 |
| conductor (mm) | |
| Diameter of the outer conductor (mm) | 28.264 |
| Overall diameter of the cable (mm) | 29.052 |
| Cross-sectional area of the cable (mm²) | 662.86 |
| Weight per unit length of the cable (kg · m⁻¹) | 1.8329 |
| J (g · mm) | 1214.956 |

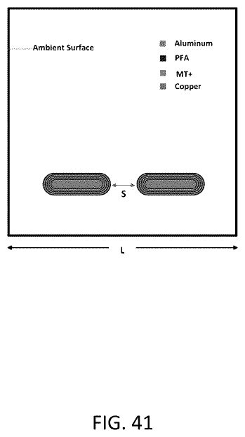

Table XXII presents the geometrical configuration and analyzed data for rectangular bipolar cable systems. The data presents the distance between the cables, core conductor's length and width, overall cable length and width, cross-sectional area of the cable, weight per unit length of the cable, and J of the cable systems as disclosed above. The geometry of the rectangular bipolar cable systems is depicted in FIG. 41.

TABLE XXII

| | | | | | Cross | | |
|---|---|---|---|---|---|---|---|
| Distance | Core | Core | Cable | Cable | sectional | Weight | |
| between | conductor | conductor | total | total | area of | per unit | |
| the cables | length | width | length | width | the cable | length | J |
| (inch) | (mm) | (mm) | (mm) | (mm) | (mm²) | (kg · m⁻¹) | (g · mm) |
| 0 | 34.37 | 6.87 | 35.16 | 7.66 | 534.45 | 1.5380 | 821.98 |
| 0.5 | 32.68 | 6.54 | 33.47 | 7.32 | 486.27 | 1.4033 | 682.38 |
| 1 | 32.38 | 6.48 | 33.17 | 7.26 | 477.89 | 1.3794 | 659.20 |
| 1.5 | 32.14 | 6.43 | 32.94 | 7.22 | 471.42 | 1.3617 | 641.93 |
| 2 | 32.05 | 6.41 | 32.84 | 7.20 | 468.97 | 1.3548 | 635.36 |

As it can be seen from the data, the lowest weight per unit length, thus the lowest J for rectangular bipolar cable systems is found for S=2 inches distance. The overall cross-sectional area also decreases when the distance between the cables increases. Therefore, the minimum J is found for S=2 inches distance between the cables, 635.36 g·mm, which is about 22.7% lower than the J found for S-0 inches distance.

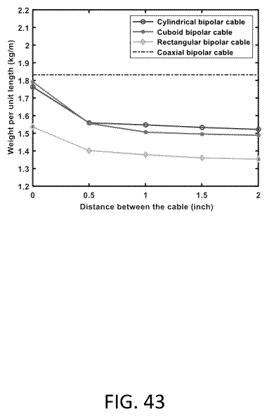

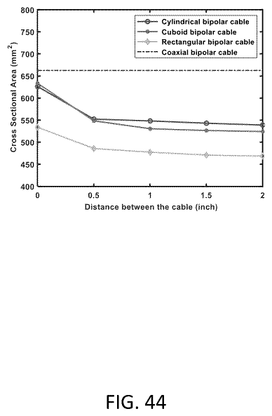

FIGS. 43-44 compare the four types of bipolar cable systems in terms of weight per unit length and cross-sectional area. As shown in FIGS. 43-44, for cylindrical, cuboid, and rectangular bipolar cable systems, when the distance between the cables is 0 inches, both the weight per unit length and the cross-sectional area are higher compared to larger distances.

Table XXI presents the geometrical configuration and analyzed data for coaxial bipolar cable systems. The geometry of the coaxial bipolar cable systems is depicted in FIG. 42. The voltage of the inner and outer conductors are +5 kV and −5 kV, respectively and both conductors are designed for carrying the same ampacity of current, 1000 A. The coaxial bipolar cable's overall diameter is 29.052 mm and the weight per unit length of the cable is 1.8329 kgm⁻¹.

The lowest weight per unit length and cross-sectional area are found at 2 inches between the cables for cylindrical, cuboid, and rectangular bipolar cables. At S=2 inches, the weight per unit length of rectangular bipolar cables is 1.3548 kg·m⁻¹ which is about 9% and 11.5% smaller than the cuboid and cylindrical bipolar cables, respectively, and 26% smaller than coaxial bipolar cables. Similar types of results are also found in terms of cross-sectional area. The rectangular bipolar cables at S=2 inches have the lowest cross-sectional area than the other cables.

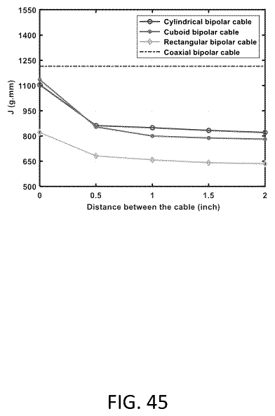

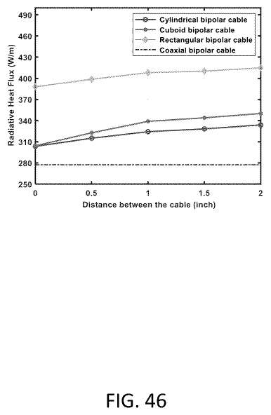

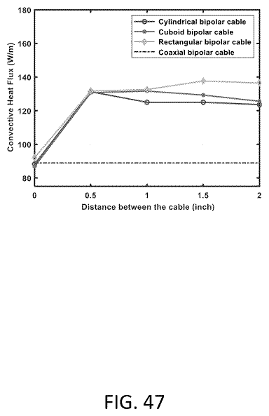

In FIG. 45, the parameter J of four types of bipolar cable systems is shown. The change in the J of cylindrical, cuboid, and rectangular bipolar cable systems follows a consistent pattern, with larger values observed at S=0 inches compared to S=2 inches. The cuboid bipolar cable system has a smaller J than the cylindrical one at distances of S=0.5, 1, 1.5, and 2 inches, except at S=0 inches but has a larger J than the rectangular bipolar cables at all distances between the cables. So, at a particular distance between the cables, the lowest value of J is found for rectangular bipolar cables. At S=0 inches, J of the rectangular bipolar cable systems is 821.98, which is 25.5% and 27.61% lower than the cylindrical bipolar cable systems and cuboid bipolar systems, respectively and 32.34% lower than the coaxial bipolar cable systems. At S=2 inches, J of the rectangular bipolar cable systems is 635.36, which is 22.62% and 18.7% lower than the cylindrical bipolar cable systems and cuboid bipolar systems, respectively and 47.66% lower than the coaxial bipolar cable systems. The weight per unit length, cross-sectional area, and J of cylindrical, cuboid, and rectangular bipolar cable systems significantly decreases as the cable distance increases from 0 inches to 2 inches. However, as the distance between the cables is increased further, the rates of reduction tend to decrease slowly. To better understand these trends and analyze the influencing parameters, the radiative and convective heat fluxes of four types of cables are shown in FIGS. 46-47. As the distance between the poles increases, the radiative heat flux of cylindrical, cuboid, and rectangular bipolar cable systems increases. However, higher radiative heat transfer is found for rectangular bipolar cable systems than the cuboid and cylindrical bipolar cable systems, since the changes in the view factor of the poles to each other for the rectangular cable systems is greater than cuboid and cylindrical bipolar cable systems.

At S=0 inches distance between the cables, the radiative heat fluxes of cuboid and cylindrical bipolar cable systems are almost similar and that is about 304 W·m⁻¹, however, these values are about 9.5% larger than the radiative heat fluxes of coaxial cables and about 21.7% smaller than the rectangular bipolar cables. As the distance increases, the cross-sectional area of rectangular bipolar cables is smaller than that of cuboid and cylindrical bipolar cables, FIG. 44. Despite decreasing the cross-sectional area of rectangular cables, the radiative heat transfer increases as the distance between the cables increases. This is because of the varying view factor of the poles to each other of rectangular bipolar cables, which compensates for the deceased surface area rate, and produces a larger radiative heat transfer for the system at larger distances. At S=2 inches, the radiative heat fluxes of rectangular bipolar cables are 414.97 W·m⁻¹, which is about 18.5% and 24.2% larger than the cuboid and cylindrical bipolar cable systems, respectively.

FIG. 46 shows the convective heat fluxes of four types of cable systems. At S=0 inches, the convective heat fluxes of cylindrical, cuboid, and rectangular bipolar cables are much smaller than the other distances. As the cables touch each other, the lack of convection on one side drastically reduces the convective heat transfer for cylindrical, cuboid, and rectangular bipolar cable systems. The lowest convective heat transfer is found for cuboid bipolar systems at this distance, however for cylindrical, coaxial, and rectangular bipolar cable systems, the value is not so much larger. The convective heat transfer of bipolar cable systems significantly increases as the distance between the poles is increased from 0 inches. This is because larger distances allow for convective heat transfer on all sides of the cables. For cylindrical and cuboid bipolar cable systems, as the distance increases from S=0.5 inches, the convective heat transfer reduces slightly since the cross-sectional area decreases, FIG. 44. But for rectangular bipolar, the trends are not exactly similar. The maximum convective heat transfer is found at S=1.5 inches, for rectangular bipolar cables.

A decrease in the cross-sectional area of the conductor leads to an increase in resistance per unit length, resulting in greater heat losses for a given current. The total heat transfer, which includes both radiative and convective components, must be equal to the heat losses. For rectangular bipolar cable systems, as the cross-sectional area is lower than other bipolar cable systems, the total heat losses are greater, so it reflects in higher convective heat transfer. At S=2 inches, the convective heat flux of rectangular bipolar cables is about 136.56 W·m⁻¹, which is 8.6% and 10.38% higher than the cuboid and cylindrical bipolar cable systems, respectively.

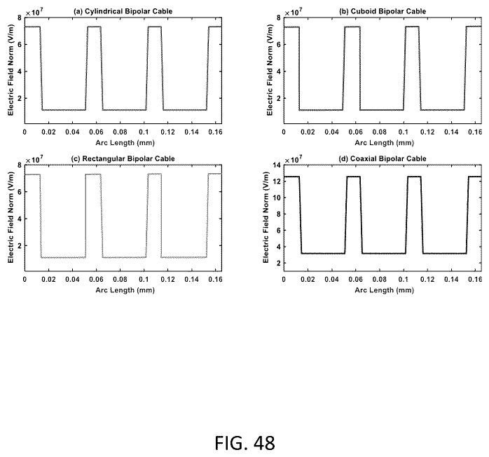

FIG. 48 displays the magnitude of the electric field across the insulation of the bipolar cable systems. The electric field norm in cylindrical, cuboid, and rectangular bipolar cable systems is the same because the insulation thickness and potential difference across the insulation are equal. But in contrast to other bipolar cable systems, the coaxial cable system's insulation has a greater potential difference, 10 kV, which raises the electric field norm throughout the insulation.

Equations (113)-(115) can be used to determine the distribution of the electric field across the insulation of DC cable systems. The electric field distribution in DC cable systems is influenced by both conductivity and permittivity.

As a result, the ratio of electric field intensity for the insulating layers in bipolar cable systems does not just match the ratio of the permittivity of the layer. All bipolar cable systems are electrically safe to operate in a steady state.

Disclosed is a detailed analysis of bipolar MVDC power cable systems for future wide-body AEA's EPS, focusing on high-power density and low-system-mass requirements. Four types of bipolar cable systems are considered: cylindrical, cuboid, rectangular, and coaxial. Multilayer insulation systems are used to address challenges in aviation cables, such as arc tracking, PDs, and thermal management. A coupled thermal, electric, and fluid flow dynamic model is developed to conduct thermal and electrical analyses of the disclosed cable systems. To assess the viability of the suggested cable systems, a parameter J is introduced, which is calculated by multiplying the weight per unit of the cables by their cross-sectional area. The rectangular bipolar cable system exhibited superior performance compared to cylindrical, cuboid, and coaxial systems in terms of J, irrespective of the distance between the poles. At S=2 inches, the J values of the rectangular bipolar cable systems are 22.62%, 18.7%, and 47.66% lower than those of the cylinder bipolar systems, cuboid bipolar systems, and coaxial bipolar cable systems, respectively. Also, the analysis of the electric field norm across bipolar cable insulation reveals that all designed systems are electrically safe in steady-state conditions.

What is claimed is:

1. A cable for use in high power delivery and low system mass electric power systems (EPSs) in electrified aircraft; the cable comprising:
at least one conductor;
at least one insulator; and
a jacket.
